(19) United States
(12) Patent Application Publication
(10) Pub. No.: US 2025/0056945 A1
(43) Pub. Date: Feb. 13, 2025

(54) LIGHT-EMITTING DEVICE AND LIGHT-EMITTING MODULE

(71) Applicant: NICHIA CORPORATION, Anan-shi (JP)

(72) Inventor: Rikita HARA, Tokushima-shi (JP)

(73) Assignee: NICHIA CORPORATION, Anan-shi (JP)

(21) Appl. No.: 18/755,275

(22) Filed: Jun. 26, 2024

(30) Foreign Application Priority Data
Aug. 7, 2023 (JP) 2023-128699
Mar. 5, 2024 (JP) 2024-033230

(51) Int. Cl. H01L 33/62; H01L 25/075

(52) U.S. Cl. CPC H01L 33/62; H01L 25/0753

(57) ABSTRACT

A light-emitting device includes: a light-emitting element including a first surface, a second surface, and a plurality of third surfaces, the light-emitting element including: a first conductive member and a second conductive member positioned at the second surface and arranged in a first direction; a covering member including: a first covering part covering a region of the second surface between the first conductive member and the second conductive member, and a second covering part covering the plurality of third surfaces, where the covering member does not cover at least a portion of the first conductive member and at least a portion of the second conductive member; a first metal film covering a portion of the first covering part; and a second metal film separated from the first metal film, the second metal film covering a portion of the first covering part.

### CROSS-REFERENCE TO RELATED APPLICATIONS

This application is based upon and claims the benefit of priority from the prior Japanese Patent Application No. 2023-128699, filed on Aug. 7, 2023, and the prior Japanese Patent Application No. 2024-033230, filed on Mar. 5, 2024, the entire contents of which are incorporated herein by reference.

### FIELD

Embodiments described herein relate generally to a light-emitting device and a light-emitting module.

### BACKGROUND

Japanese Patent Publication No. 2012-124191 discusses a lateral surface-emitting light-emitting device. The lateral surface-emitting light-emitting device emits light mainly in a direction parallel to amounting surface of the light-emitting device. It is desirable to further improve the bondability of the lateral surface-emitting light-emitting device with the substrate to which the lateral surface-emitting light-emitting device is mounted.

### SUMMARY

According to one aspect of the present disclosure, a light-emitting device includes a light-emitting element, a covering member, a first metal film, and a second metal film. The light-emitting element includes a first surface, a second surface positioned at a side opposite to the first surface, a plurality of third surfaces positioned between the first surface and the second surface, and a first conductive member and a second conductive member positioned at the second surface and arranged in a first direction. The covering member includes a first covering part covering a region of the second surface between the first conductive member and the second conductive member, and a second covering part covering the plurality of third surfaces. The covering member does not cover at least a portion of the first conductive member and at least a portion of the second conductive member. The first metal film covers a portion of the first covering part. The first metal film is connected to the first conductive member. The second metal film is separated from the first metal film. The second metal film covers a portion of the first covering part. The second metal film is connected to the second conductive member. In a second direction from the second surface toward the first surface, a maximum length of the first covering part is greater than a maximum length of the first conductive member, and a maximum length of the first metal film is greater than the maximum length of the first conductive member.

According to one aspect of the present invention, a light-emitting module includes the light-emitting device, a substrate, and a first connection member. The substrate includes a mounting surface, and a first terminal and a second terminal positioned on the mounting surface. The first connection member contacts the first terminal and the first metal film. The first metal film includes a first portion covering the first conductive member. The first portion includes a first region contacting the first connection member. The first metal film includes a second portion covering the second covering part. The second portion includes a second region contacting the first connection member. A first proportion of the first region in the first portion is greater than a second proportion of the second region in the second portion.

### BRIEF DESCRIPTION OF THE DRAWINGS

FIG. 1 is a front view illustrating a light-emitting device according to a first embodiment;

FIG. 2 is a back view illustrating the light-emitting device according to the first embodiment;

FIG. 3 is a side view illustrating the light-emitting device according to the first embodiment;

FIG. 4 is a top view illustrating the light-emitting device according to the first embodiment;

FIG. 5 is a cross-sectional view along line V-V shown in FIG. 1;

FIG. 6 is a partially enlarged sectional view illustrating region VI in FIG. 5;

FIG. 7A is a plan view illustrating a method for manufacturing the light-emitting device according to the first embodiment;

FIG. 7B is a cross-sectional view along line VIIB-VIIB shown in FIG. 7A;

FIG. 8A is a plan view illustrating the method for manufacturing the light-emitting device according to the first embodiment;

FIG. 8B is a cross-sectional view along line VIIIB-VIIIB shown in FIG. 8A;

FIG. 9A is a plan view illustrating the method for manufacturing the light-emitting device according to the first embodiment;

FIG. 9B is a cross-sectional view along line IXB-IXB shown in FIG. 9A;

FIG. 10A is a plan view illustrating the method for manufacturing the light-emitting device according to the first embodiment;

FIG. 10B is a cross-sectional view along line XB-XB shown in FIG. 10A;

FIG. 11A is a plan view illustrating the method for manufacturing the light-emitting device according to the first embodiment;

FIG. 11B is a cross-sectional view along line XIB-XIB shown in FIG. 11A;

FIG. 12A is a plan view illustrating the method for manufacturing the light-emitting device according to the first embodiment;

FIG. 12B is a cross-sectional view along line XIIB-XIIB shown in FIG. 12A;

FIG. 13A is a plan view illustrating the method for manufacturing the light-emitting device according to the first embodiment;

FIG. 13B is a cross-sectional view along line XIIIB-XIIIB shown in FIG. 13A;

FIG. 14A is a plan view illustrating the method for manufacturing the light-emitting device according to the first embodiment;

FIG. 14B is a cross-sectional view along line XIVB-XIVB shown in FIG. 14A;

FIG. 15 is a back view illustrating a light-emitting module according to the first embodiment;

FIG. 16 is a cross-sectional view along line XVI-XVI shown in FIG. 15;

FIG. 17 is a cross-sectional view along line XVII-XVII shown in FIG. 15;

FIG. 18 is a back view illustrating a light-emitting device according to a second embodiment;

FIG. 19 is a cross-sectional view along line IX-IX shown in FIG. 18;

FIG. 20 is a back view illustrating a light-emitting device according to a third embodiment;

FIG. 21 is a back view illustrating a light-emitting device according to a fourth embodiment;

FIG. 22 is a top view illustrating the light-emitting device according to the fourth embodiment;

FIG. 23 is a cross-sectional view illustrating a light-emitting device according to a fifth embodiment;

FIG. 24 is a front view illustrating a light-emitting device according to a sixth embodiment;

FIG. 25 is a back view illustrating the light-emitting device according to the sixth embodiment;

FIG. 26 is a cross-sectional view along line XXVI-XXVI shown in FIG. 25;

FIG. 27 is a cross-sectional view along line XXVII-XXVII shown in FIG. 25;

FIG. 28 is a cross-sectional view along line XXVIII-XXVIII shown in FIG. 25;

FIG. 29 is a perspective view illustrating the light-emitting device according to the sixth embodiment;

FIG. 30A is a back view illustrating a method for manufacturing the light-emitting device according to the sixth embodiment;

FIG. 30B is a cross-sectional view along line XXXB-XXXB shown in FIG. 30A;

FIG. 30C is a cross-sectional view along line XXXC-XXXC shown in FIG. 30A;

FIG. 30D is a cross-sectional view along line XXXD-XXXD shown in FIG. 30A;

FIG. 31A is a back view illustrating the method for manufacturing the light-emitting device according to the sixth embodiment;

FIG. 31B is a cross-sectional view along line XXXIB-XXXIB shown in FIG. 31A;

FIG. 31C is a cross-sectional view along line XXXIC-XXXIC shown in FIG. 31A;

FIG. 31D is a cross-sectional view along line XXXID-XXXID shown in FIG. 31A;

FIG. 32A is a back view illustrating the method for manufacturing the light-emitting device according to the sixth embodiment;

FIG. 32B is a cross-sectional view along line XXXIIB-XXXIIB shown in FIG. 32A;

FIG. 32C is a cross-sectional view along line XXXIIC-XXXIIC shown in FIG. 32A;

FIG. 32D is a cross-sectional view along line XXXIID-XXXIID shown in FIG. 32A;

FIG. 33A is a back view illustrating the method for manufacturing the light-emitting device according to the sixth embodiment;

FIG. 33B is a cross-sectional view along line XXXIIIB-XXXIIIB shown in FIG. 33A;

FIG. 33C is a cross-sectional view along line XXXIIIC-XXXIIIC shown in FIG. 33A;

FIG. 33D is a cross-sectional view along line XXXIIID-XXXIIID shown in FIG. 33A;

FIG. 34A is a back view illustrating the method for manufacturing the light-emitting device according to the sixth embodiment;

FIG. 34B is a cross-sectional view along line XXXIVB-XXXIVB shown in FIG. 34A;

FIG. 34C is a cross-sectional view along line XXXIVC-XXXIVC shown in FIG. 34A;

FIG. 34D is a cross-sectional view along line XXXIVD-XXXIVD shown in FIG. 34A;

FIG. 35A is a back view illustrating the method for manufacturing the light-emitting device according to the sixth embodiment;

FIG. 35B is a cross-sectional view along line XXXVB-XXXVB shown in FIG. 35A;

FIG. 35C is a cross-sectional view along line XXXVC-XXXVC shown in FIG. 35A;

FIG. 35D is a cross-sectional view along line XXXVD-XXXVD shown in FIG. 35A;

FIG. 36A is a back view illustrating the method for manufacturing the light-emitting device according to the sixth embodiment;

FIG. 36B is a cross-sectional view along line XXXVIB-XXXVIB shown in FIG. 36A;

FIG. 36C is a cross-sectional view along line XXXVIC-XXXVIC shown in FIG. 36A;

FIG. 36D is a cross-sectional view along line XXXVID-XXXVID shown in FIG. 36A;

FIG. 37A is a back view illustrating the method for manufacturing the light-emitting device according to the sixth embodiment;

FIG. 37B is a cross-sectional view along line XXXVIIB-XXXVIIB shown in FIG. 37A;

FIG. 37C is a cross-sectional view along line XXXVIIC-XXXVIIC shown in FIG. 37A;

FIG. 37D is a cross-sectional view along line XXXVIID-XXXVIID shown in FIG. 37A;

FIG. 38 is a front view illustrating a light-emitting device according to a seventh embodiment;

FIG. 39 is a back view illustrating the light-emitting device according to the seventh embodiment;

FIG. 40 is a side view illustrating the light-emitting device according to the seventh embodiment;

FIG. 41 is a cross-sectional view illustrating the light-emitting device according to the seventh embodiment;

FIG. 42 is a top view illustrating the light-emitting device according to the seventh embodiment;

FIG. 43 is a cross-sectional view illustrating the light-emitting device according to the seventh embodiment;

FIG. 44 is a partially enlarged sectional view illustrating region XLIV in FIG. 43;

FIG. 45 is a perspective view illustrating the light-emitting device according to the seventh embodiment;

FIG. 46 is a top view illustrating a light-emitting module according to the seventh embodiment;

FIG. 47 is a cross-sectional view illustrating a light-emitting device according to an eighth embodiment;

FIG. 48 is a front view illustrating a light-emitting device according to a ninth embodiment;

FIG. 49 is a back view illustrating the light-emitting device according to the ninth embodiment;

FIG. 50 is a front view illustrating a light-emitting device according to a tenth embodiment;

FIG. 51 is a front view illustrating a light-emitting device according to an eleventh embodiment;

FIG. 52 is a back view illustrating the light-emitting device according to the eleventh embodiment;

FIG. 53 is a cross-sectional view illustrating the light-emitting device according to the eleventh embodiment; and

FIG. 54 is a bottom view illustrating a top surface-emitting light-emitting device according to a reference example.

### DETAILED DESCRIPTION

### First Embodiment

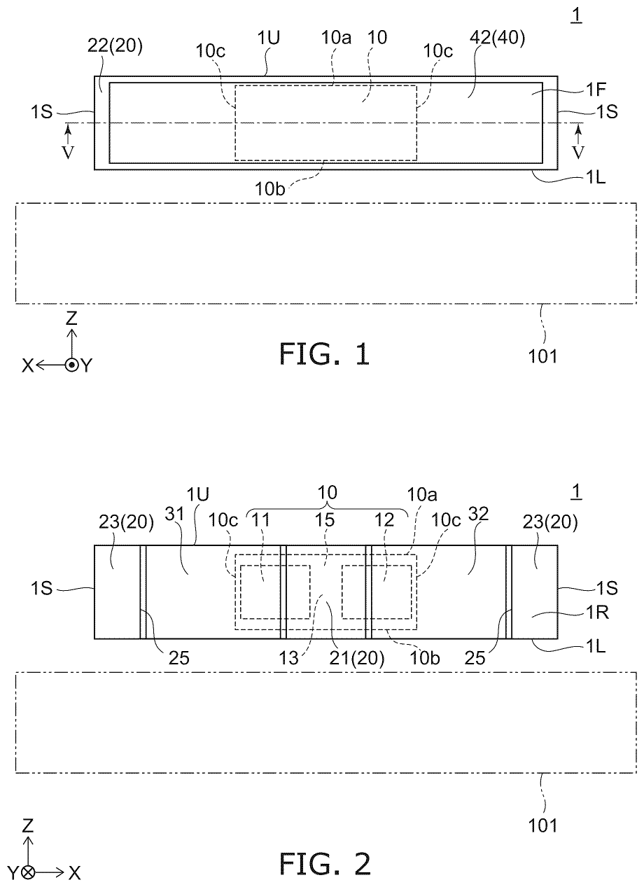

A light-emitting device 1 of a first embodiment is described with reference to FIGS. 1 to 6. The drawings are schematic and may be enhanced and simplified as appropriate. End views that show only cross sections may be used as cross-sectional views. The dimensional ratios do not necessarily match between the drawings, even for the same components. This applies to the other drawings described below as well.

As shown in FIGS. 1 to 6, the light-emitting device 1 according to the present embodiment is a lateral surface-emitting light-emitting device. In some of the drawings, a substrate 101 to which the light-emitting device 1 is mounted also is shown for easier understanding of the directions. The detailed relationship between the light-emitting device 1 and the substrate 101 is described below. The direction of light L emitted from the light-emitting device 1 is illustrated by arrows in some of the drawings.

In the light-emitting device 1 of the following description, the emission surface of the light is called a “front surface 1F,” the surface at the side opposite to the front surface 1F is called a “back surface 1R,” the surface that faces the substrate 101 to which the light-emitting device 1 is mounted is called a “lower surface 1L,” the surface at the side opposite to the lower surface 1L is called an “upper surface 1U,” and two surfaces surrounded with the front surface 1F, the back surface 1R, the lower surface 1L, and the upper surface 1U are called “side surfaces 1S.” However, these expressions are for convenience, and are independent of the direction of gravity.

An XYZ orthogonal coordinate system is employed for convenience of description in the specification. The direction that connects the two side surfaces 1S of the light-emitting device 1 is taken as a “first direction X,” the direction from the back surface 1R toward the front surface 1F is taken as a “second direction Y,” and the direction from the lower surface 1L toward the upper surface 1U is taken as a “third direction Z.” The first direction X and the opposite direction of the first direction X are differentiated as the “+X direction” and the “−X direction” as necessary. The same concept applies to the second and third directions Y and Z as well.

The light-emitting device 1 according to the present embodiment includes a light-emitting element 10, a covering member 20, a first metal film 31, and a second metal film 32. The light-emitting device 1 may further include a light-transmitting member 40.

The light-emitting element 10 includes a first surface 10a, a second surface 10b positioned at the side opposite to the first surface 10a, and multiple third surfaces 10c positioned between the first surface 10a and the second surface 10b. In an example, the light-emitting element 10 has a substantially rectangular parallelepiped shape and includes four third surfaces 10c. The light-emitting element 10 also includes a semiconductor stacked body 15, a first conductive member 11, and a second conductive member 12. The semiconductor stacked body 15 includes, for example, a substrate including sapphire, gallium nitride, or the like, an n-type semiconductor layer, a p-type semiconductor layer, and a light-emitting layer interposed between the n-type semiconductor layer and the p-type semiconductor layer. The substrate, the n-type semiconductor layer, the light-emitting layer, and the p-type semiconductor layer are stacked along the second direction Y.

The light-emitting layer may have a structure that includes a single active layer such as a double heterostructure or a single quantum well structure (SQW), or may have a structure that includes an active layer group such as a multi-quantum well structure (MQW). The light-emitting layer is configured to emit visible light or ultraviolet light. The light-emitting layer is configured to emit blue to red as the visible light. The semiconductor stacked body that includes such a light-emitting layer can include, for example, InₓAl_{y}Ga_{1-x-y}N (0≤x, 0≤y, and x+y≤1). The semiconductor stacked body can include at least one light-emitting layer capable of the light emission described above. For example, the semiconductor stacked body may have a structure that includes one or more light-emitting layers between the n-type semiconductor layer and the p-type semiconductor layer, or may have a structure in which the structure including the n-type semiconductor layer, the light-emitting layer, and the p-type semiconductor layer in this order is multiply repeated. When the semiconductor stacked body includes multiple light-emitting layers, the multiple light-emitting layers may have different light emission peak wavelengths, or may have the same light emission peak wavelength. The same light emission peak wavelengths means that, for example, there may be variation about several nm. Such combinations of light-emitting layers can be selected as appropriate; for example, when the semiconductor stacked body includes two light-emitting layers, the light-emitting layers can be selected to have a combination of blue light and blue light, green light and green light, red light and red light, ultraviolet light and ultraviolet light, blue light and green light, blue light and red light, green light and red light, etc. The light-emitting layer may include multiple active layers of different light emission peak wavelengths, or may include multiple active layers of the same light emission peak wavelength. The light-emitting element 10 is, for example, a light-emitting diode (LED), and emits, for example, blue light.

The first conductive member 11 and the second conductive member 12 are positioned at the second surface 10b of the light-emitting element 10 and arranged in the first direction X. The first conductive member 11 is connected to the p-type semiconductor layer of the semiconductor stacked body 15, and the second conductive member 12 is connected to the n-type semiconductor layer of the semiconductor stacked body 15. In the present disclosure, “connected” means an electrical connection.

The first conductive member 11 includes both a p-side electrode connected to the p-type semiconductor layer, and a p-side post connected to the p-side electrode. The light-emitting element 10 does not have to include a p-side post. When the light-emitting element 10 does not include a p-side post, the first conductive member 11 is formed of the p-side electrode. The second conductive member 12 includes both an n-side electrode connected to the n-type semiconductor layer, and an n-side post connected to the n-side electrode. The light-emitting element 10 does not have to include an n-side post. When the light-emitting element 10 does not include an n-side post, the second conductive member 12 is formed of the n-side electrode. The p-side post and the n-side post include, for example, copper (Cu) and/or nickel (Ni).

The covering member 20 includes a first covering part 21 and a second covering part 22. The first covering part 21 covers a region 13 of the second surface 10b of the light-emitting element 10 between the first conductive member 11 and the second conductive member 12. The second covering part 22 covers the multiple third surfaces 10c of the light-emitting element 10. The second covering part 22 covers a portion of the second surface 10b of the light-emitting element 10. The covering member 20 does not cover at least a portion of the first conductive member 11 and at least a portion of the second conductive member 12. The first covering part 21 preferably overlaps a portion of the first conductive member 11 and a portion of the second conductive member 12 in the second direction Y.

The covering member 20 may further include a third covering part 23. The third covering part 23 overlaps the first covering part 21 in the first direction X, and overlaps the second covering part 22 in the second direction Y According to the present embodiment, two third covering parts 23 are included, and are located at the two sides of the first covering part 21 in the first direction X. The two third covering parts 23 are respectively located at the −Y direction side of the second covering parts 22.

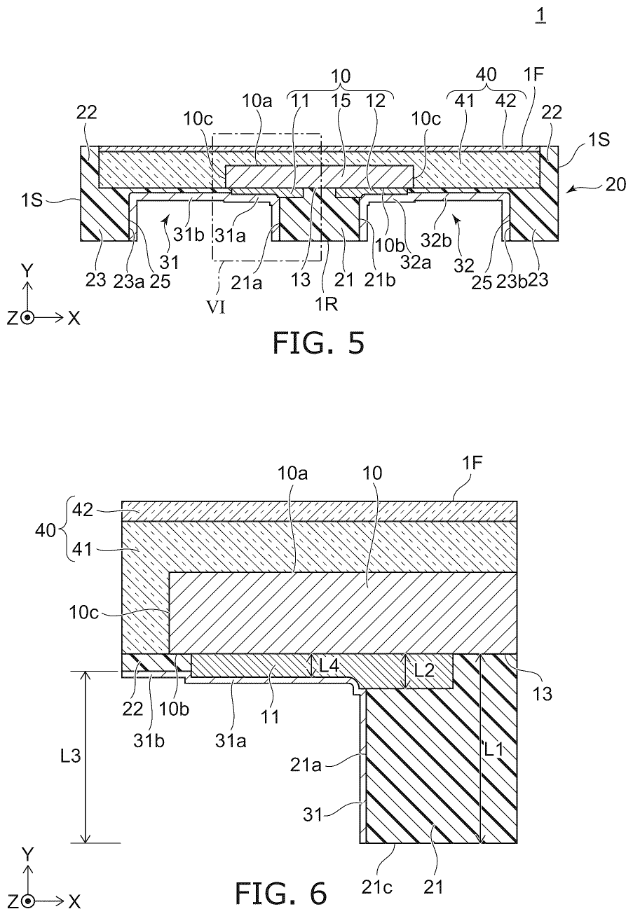

For example, the covering member 20 is monolithically formed of a white resin material as a continuous body. A recessed portion 25, of which at least a portion is defined by the first and third covering parts 21 and 23, is open at the two ends of the covering member 20 in the third direction Z. In other words, the recessed portion 25 extends through the covering member 20 along the third direction Z and reaches the upper surface 1U and the lower surface 1L. Two recessed portions 25 are formed, and the two recessed portions 25 are arranged along the first direction X. The first covering part 21 is located between the two recessed portions 25. As shown in FIG. 5, in the second direction Y, portions of the two recessed portions 25 overlap the light-emitting element 10, and other portions of the two recessed portions 25 do not overlap the light-emitting element 10. Because the other portions of the two recessed portions 25 do not overlap the light-emitting element 10 in the second direction Y, the length of the recessed portion 25 in the first direction X can be increased.

The first metal film 31 covers a portion of the first covering part 21 of the covering member 20 and is connected to the first conductive member 11. For example, the first metal film 31 covers a side surface 21a of the first covering part 21 and contacts the first conductive member 11. The second metal film 32 is separated from the first metal film 31, partially covers the first covering part 21 of the covering member 20, and is connected to the second conductive member 12. For example, the second metal film 32 covers a side surface 21b of the first covering part 21 and contacts the second conductive member 12. The side surfaces 21a and 21b of the first covering part 21 are positioned at the two sides of the first covering part 21 in the first direction X and spread substantially along the YZ-plane.

The first metal film 31 may cover a portion of the back surface of the second covering part 22 and at least a portion of the side surface of the third covering part 23. According to the present embodiment, the first metal film 31 covers at least a portion of a side surface 23a of the third covering part 23. The side surface 23a of the third covering part 23 faces the side surface 21a of the first covering part 21. Similarly, the second metal film 32 may cover a portion of the back surface of the second covering part 22 and at least a portion of the side surface of the third covering part 23. According to the present embodiment, the second metal film 32 covers at least a portion of a side surface 23b of the third covering part 23. The side surface 23b of the third covering part 23 faces the side surface 21b of the first covering part 21. According to the present embodiment, the first metal film 31 is provided over the entire inner surface defining one recessed portion 25, and the second metal film 32 is provided over the entire inner surface defining the other recessed portion 25.

A portion 31a of the first metal film 31 covering the first conductive member 11 protrudes toward the −Y direction side with respect to the periphery of the portion 31a covering the first conductive member 11. Also, the surface roughness of the portion 31a covering the first conductive member 11 is less than the surface roughness of a portion 31b of the first metal film 31 covering the second covering part 22. Similarly, a portion 32a of the second metal film 32 covering the second conductive member 12 protrudes toward the −Y direction side with respect to the periphery of the portion 32a covering the second conductive member 12. Also, the surface roughness of the portion 32a is less than the surface roughness of a portion 32b of the second metal film 32 covering the second covering part 22. The first metal film 31 and the second metal film 32 may be, for example, a (Ni/Ru/Au) three-layer film in which a nickel layer, a ruthenium layer, and a gold layer are stacked, or a (Ni/Au) two-layer film in which a nickel layer and a gold layer are stacked.

In the specification, “surface roughness” refers to the arithmetic average roughness Ra defined in JIS Standard B0601:2013. The arithmetic average roughness Ra can be measured using a laser microscope, a contact-type surface roughness tester, etc. For example, the surface roughness can be measured using the laser microscope VK-X1100 (lens magnification: 5 times) made by Keyence.

As shown in FIG. 6, in the second direction Y, a maximum length L1 of the first covering part 21 is greater than a maximum length L2 of the first conductive member 11. In the second direction Y, a maximum length L3 of the first metal film 31 is greater than the maximum length L2 of the first conductive member 11. In other words, L1>L2, and L3>L2.

For example, in the second direction Y, the maximum length L1 of the first covering part 21 is not less than 2 times and not more than 50 times the maximum length L2 of the first conductive member 11. In the second direction Y, the maximum length L3 of the first metal film 31 is not less than 0.7 times and not more than 1.2 times the maximum length L1 of the first covering part 21.

In the example shown in FIGS. 5 and 6, the first metal film 31 is provided over the entire side surface 21a of the first covering part 21, and is not located on a back surface 21c of the first covering part 21. In such a case, the maximum length L3 of the first metal film 31 is less than the maximum length L1 of the first covering part 21. On the other hand, when the first metal film 31 is located on the back surface 21c of the first covering part 21, the maximum length L3 of the first metal film 31 may be not less than the maximum length L1 of the first covering part 21.

Similarly, in the second direction Y, the maximum length of the first covering part 21 is greater than the maximum length of the second conductive member 12. In the second direction Y, the maximum length of the second metal film 32 is greater than the maximum length of the second conductive member 12. For example, in the second direction Y, the maximum length of the first covering part 21 is not less than 2 times and not more than 50 times the maximum length of the second conductive member 12. In the second direction Y, the maximum length of the second metal film 32 is not less than 0.7 times and not more than 1.2 times the maximum length of the first covering part 21.

As shown in FIG. 6, the maximum thickness of the portion of the first conductive member 11 covered with the first covering part 21, i.e., the maximum length L2 in the second direction Y, is greater than the maximum thickness of the portion of the first conductive member 11 not covered with the first covering part 21, i.e., a maximum length L4 in the second direction Y In other words, L2>L4. The maximum length L2 is preferably not less than 1.5 times and not more than 4 times the maximum length L4.

When the light-emitting device 1 includes the light-transmitting member 40, the light-transmitting member 40 is positioned between the second covering part 22 of the covering member 20 and the third surface 10c of the light-emitting element 10. The third covering part 23 overlaps the light-transmitting member 40 in the second direction Y According to the present embodiment, the light-transmitting member 40 includes a wavelength conversion layer 41 and a light-transmitting layer 42. The wavelength conversion layer 41 includes a phosphor, such as, for example, a phosphor that absorbs blue light emitted from the light-emitting element 10 and emits red light, and a phosphor that absorbs the blue light emitted from the light-emitting element 10 and emits green light. The wavelength conversion layer 41 may include a phosphor that absorbs blue light and emits yellow light. The light-transmitting layer 42 substantially does not include a phosphor.

Oxynitride-based phosphors such as an yttrium-aluminum-garnet-based phosphor (e.g., (Y, Gd)₃(Al, Ga)₅O₁₂:Ce), a lutetium-aluminum-garnet-based phosphor (e.g., Lu₃(Al, Ga)₅O₁₂:Ce), a terbium-aluminum-garnet-based phosphor (e.g., Tb₃(Al, Ga)₅O₁₂:Ce), a CCA-based phosphor (e.g., Ca₁₀(PO₄)₆Cl₂:Eu), an SAE-based phosphor (e.g., Sr₄Al₁₄O₂₅:Eu), a chlorosilicate-based phosphor (e.g., Ca₈MgSi₄O₁₆Cl₂:Eu), a silicate-based phosphor (e.g., (Ba, Sr, Ca, Mg)₂SiO₄:Eu), a β-sialon-based phosphor (e.g., (Si, Al)₃(O, N)₄:Eu), an α-sialon-based phosphor (e.g., Ca(Si, Al)₁₂(O, N)₁₆:Eu), or the like, nitride-based phosphors such as an LSN-based phosphor (e.g., (La, Y)₃Si₆N₁₁:Ce), a BSESN-based phosphor (e.g., (Ba, Sr)₂Si₅N₈:Eu), an SLA-based phosphor (e.g., SrLiAl₃N₄:Eu), a CASN-based phosphor (e.g., CaAlSiN₃:Eu), a SCASN-based phosphor (e.g., (Sr, Ca)AlSiN₃:Eu), or the like, fluoride-based phosphors such as a KSF-based phosphor (e.g., K₂SiF₆:Mn), a KSAF-based phosphor (e.g., K₂(Si₁₋ₓAlₓ)F₆₋ₓ:Mn, wherein x satisfies 0<x<1), a MGF-based phosphor (e.g., 3.5MgO·0.5MgF₂·GeO₂:Mn), or the like, a quantum dot having a perovskite structure (e.g., (Cs, FA, MA)(Pb, Sn)(F, Cl, Br, I)₃, wherein FA and MA are respectively formamidinium and methylammonium), a Group II-VI quantum dot (e.g., CdSe), a Group III-V quantum dot (e.g., InP), a quantum dot having a chalcopyrite structure (e.g., (Ag, Cu)(In, Ga)(S, Se)₂), etc., can be used as the phosphor. The phosphor that is added to the light-transmitting member 40 may be one type of phosphor, or may include multiple types of phosphors.

In the example shown in FIG. 5, the wavelength conversion layer 41 covers the first and third surfaces 10a and 10c 10, but does not cover the second surface 10b of the light-emitting element. The light-transmitting layer 42 is located at the +Y direction side of the wavelength conversion layer 41 in the second direction Y and is separated from the light-emitting element 10 with the wavelength conversion layer 41 interposed. The surfaces of the light-transmitting member 40 facing in the +X direction and the −X direction of the first direction X, the surfaces of the light-transmitting member 40 facing in the +Z direction and the −Z direction of the third direction Z, and the surface of the light-transmitting member 40 facing in the −Y direction of the second direction Y are covered with the second covering part 22 of the covering member 20. The surface of the light-transmitting member 40 facing in the +Y direction of the second direction Y is not covered with the covering member 20, and forms a main portion of the front surface 1F of the light-emitting device 1.

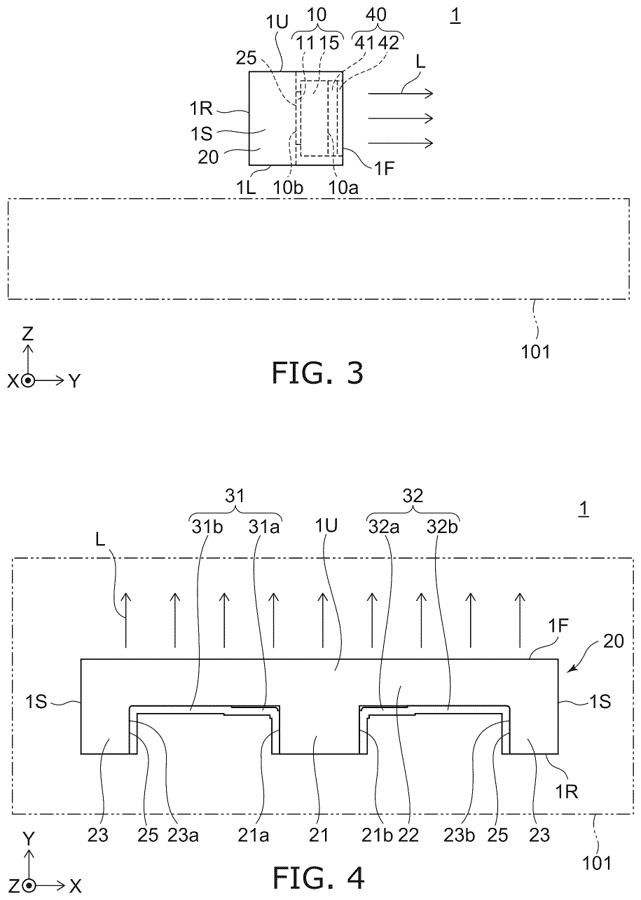

At the front surface 1F of the light-emitting device 1 as shown in FIG. 1, the light-transmitting layer 42 of the light-transmitting member 40 is exposed, and the second covering part 22 of the covering member 20 surrounds the periphery of the light-transmitting layer 42. As shown in FIG. 2, the first covering part 21 and the two third covering parts 23 of the covering member 20, the first metal film 31, and the second metal layer 32 are positioned at the back surface 1R of the light-emitting device 1. The two recessed portions 25, which have portions defined by the first covering part 21 and the two third covering parts 23 opposite to each other with respect to the first covering part 21, are positioned at the back surface 1R side of the light-emitting device 1. The first metal film 31 and the second metal layer 32 are located respectively on the inner surfaces that define the two recessed portions 25. As shown in FIG. 3, the side surfaces 1S of the light-emitting device 1 are formed of the covering member 20. At the upper surface 1U of the light-emitting device 1 as shown in FIG. 4, the covering member 20, the end surface of the first metal film 31, and the end surface of the second metal film 32 are exposed. This is similar for the lower surface 1L of the light-emitting device 1 as well.

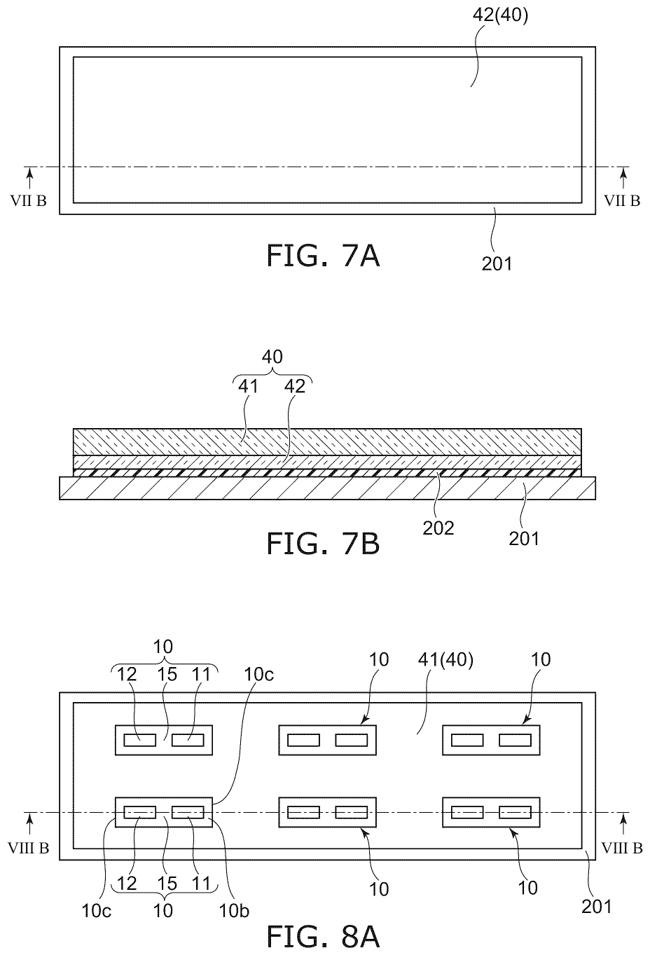

A method for manufacturing the light-emitting device 1 according to the present embodiment will now be described with reference to FIGS. 7A to 14B.

First, as shown in FIGS. 7A and 7B, the uncured light-transmitting member 40 is placed on a support substrate 201 with an adhesive layer 202 interposed. The light-transmitting member 40 includes the wavelength conversion layer 41 and the light-transmitting layer 42. The light-transmitting layer 42 contacts the adhesive layer 202. When the light-transmitting member 40 and/or the support substrate 201 has adhesiveness, the light-transmitting member 40 and/or the support substrate 201 may be fixed by contacting the light-transmitting layer 42 and the support substrate 201. In the following description of the manufacturing method, the support substrate 201 side is called “down,” and the light-transmitting member 40 side is called “up” as in FIG. 7B, etc. The adhesive layer 202 is not illustrated in FIG. 7A. This is similar for the plan views below as well.

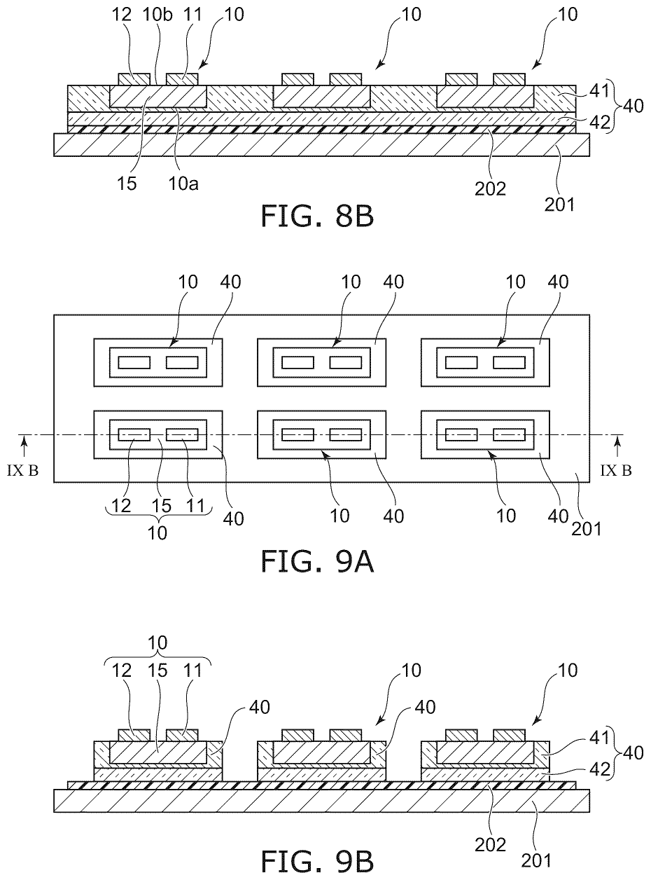

Then, as shown in FIGS. 8A and 8B, the light-emitting element 10 is put into the uncured wavelength conversion layer 41 so that the first surface 10a of the light-emitting element 10 faces the light-transmitting layer 42. Accordingly, the light-emitting element 10 is located inside the wavelength conversion layer 41. In FIG. 8A, multiple light-emitting elements are arranged in a matrix configuration. The arrangement is not limited to a matrix configuration; the multiple light-emitting elements may be regularly arranged. When the light-emitting element 10 is located inside the wavelength conversion layer 41, the first conductive member 11 and the second conductive member 12 are not covered with the wavelength conversion layer 41. The wavelength conversion layer 41 remains between the light-transmitting layer 42 and the light-emitting element 10. After the light-emitting element 10 is put into the wavelength conversion layer 41, the uncured light-transmitting member 40 is cured.

Then, as shown in FIGS. 9A and 9B, the light-transmitting member 40 is divided for each light-emitting element 10. At this time, the light-emitting element 10 is not exposed at the cross section of the light-transmitting member 40.

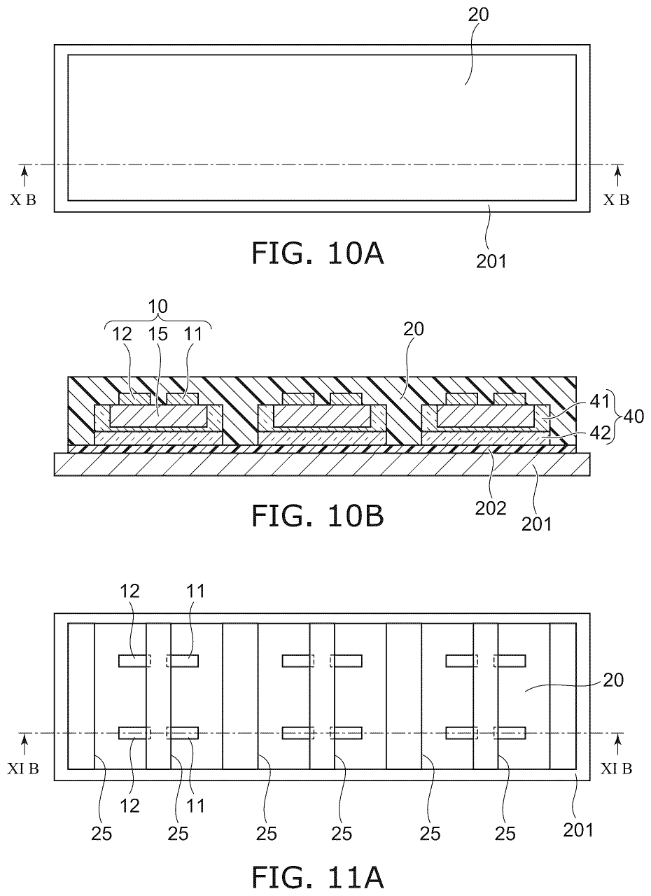

Continuing as shown in FIGS. 10A and 10B, the covering member 20 is formed by disposing a resin material on the support substrate 201, forming, curing, and polishing. The resin material includes, for example, a white resin material.

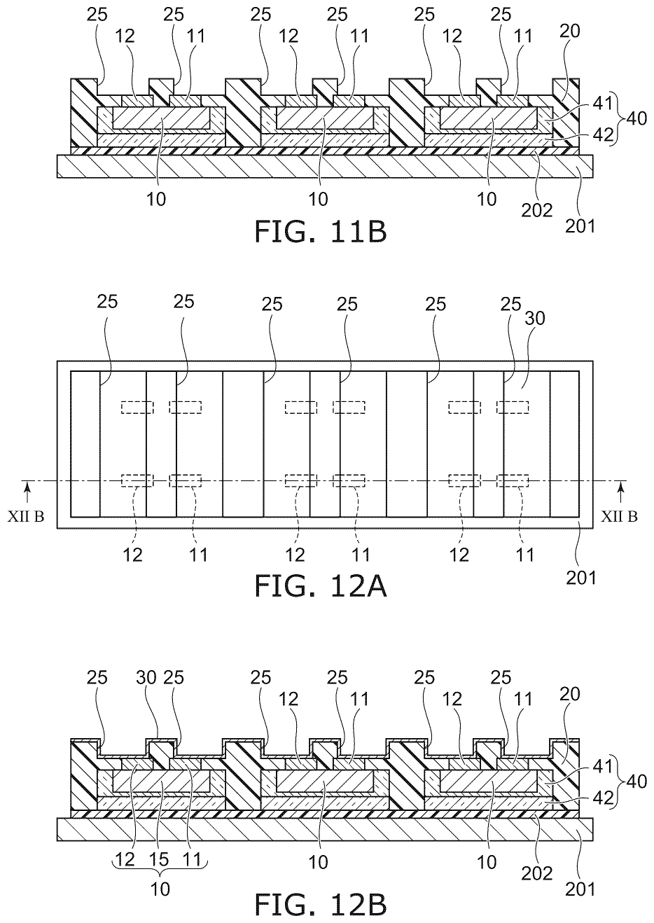

Then, as shown in FIGS. 11A and 11B, the recessed portions 25 that extend in one direction are formed by removing portions of the upper surface of the covering member 20. The recessed portions 25 that are formed at the upper surface of the covering member 20 are formed of one outer edge of the covering member 20 to the other outer edge of the covering member 20 positioned at the side opposite to the one outer edge of the covering member 20. Examples of methods of forming the recessed portions 25 in the upper surface of the covering member 20 include half-cutting with a laser or blade, etching, etc. When forming the recessed portions 25 in the upper surface of the covering member 20 by half-cutting, one recessed portion 25 may be formed by scanning the laser or blade once, or one recessed portion 25 may be formed by scanning multiple times. When forming the recessed portions 25 in the upper surface of the covering member 20 by half-cutting with a blade, a desired recessed portion shape can be obtained by adjusting the shape of the blade tip. For example, by adjusting the shape of the blade tip, the angle between the bottom surface defining the recessed portion and the side surface defining the recessed portion can be set to a right angle, or the corners of the recessed portion can be rounded. When forming one recessed portion 25 by scanning multiple times, a desired recessed portion shape can be obtained by adjusting the length of the scan.

Two recessed portions 25 are formed in each light-emitting element 10. At this time, at least a portion of the first conductive member 11 is exposed at the bottom surface defining one recessed portion 25 facing the light-emitting element 10, and at least a portion of the second conductive member 12 at the bottom surface defining the other recessed portion 25 is exposed. Because the first conductive member 11 and the second conductive member 12 are not easily polished compared with the covering member 20, the first conductive member 11 and the second conductive member 12 can slightly protrude from the covering member 20 toward the −Y direction side at the bottom surface defining the recessed portion 25. When the covering member 20 includes a resin material, the surface roughnesses of the first and second conductive members 11 and 12 at the bottom surface defining the recessed portions 25 can be set to be less than the surface roughness of the covering member 20 because resin materials are more brittle than metal materials.

Then, as shown in FIGS. 12A and 12B, a metal material is formed over the entire upper surface of the covering member 20. For example, nickel, ruthenium, and gold may be sputtered in this order, or nickel and gold may be sputtered in this order. Accordingly, a metal film 30 is located on the covering member 20. The metal film 30 also is located on the inner surface defining the recessed portions 25. At this time, the portions of the metal film 30 covering the first conductive member 11 and the second conductive member 12 can protrude toward the −Y direction side with respect to the peripheries of these portions by reflecting how the first conductive member 11 and the second conductive member 12 protrude from the covering member 20 toward the −Y direction side. The surface roughnesses of the portions of the metal film 30 covering the first conductive member 11 and the second conductive member 12 can be less than the surface roughnesses of the portions of the metal film 30 covering the covering member 20 by reflecting how the surface roughnesses of the first and second conductive members 11 and 12 are less than the surface roughness of the covering member 20.

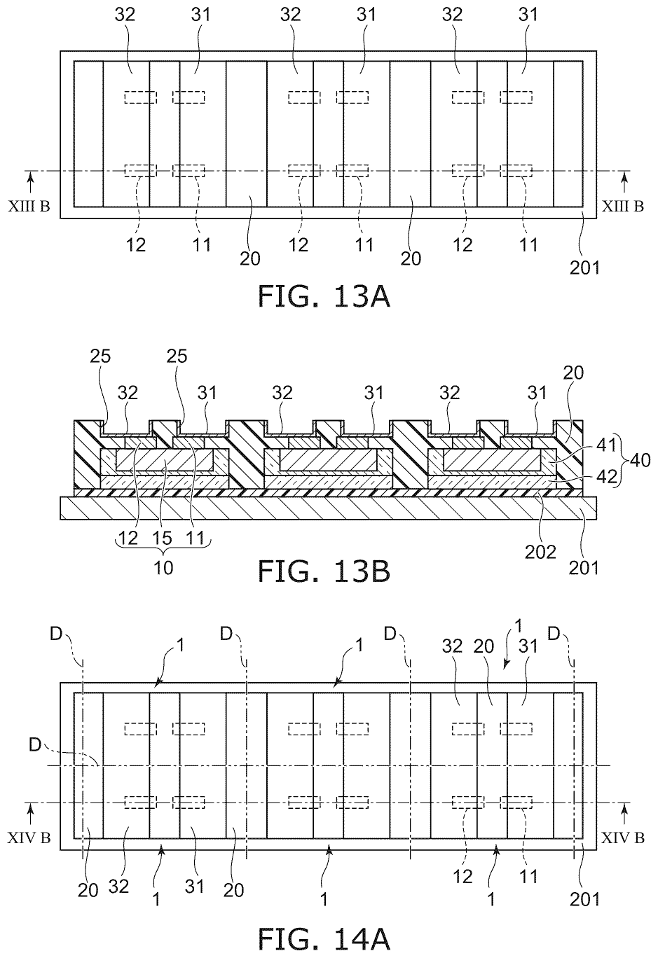

Continuing as shown in FIGS. 13A and 13B, the metal film 30 is remained only on the inner surfaces defining the recessed portions 25 by selectively removing the metal film 30 by laser ablation. Accordingly, the remainder of the metal film 30 becomes the first metal film 31 and the second metal film 32.

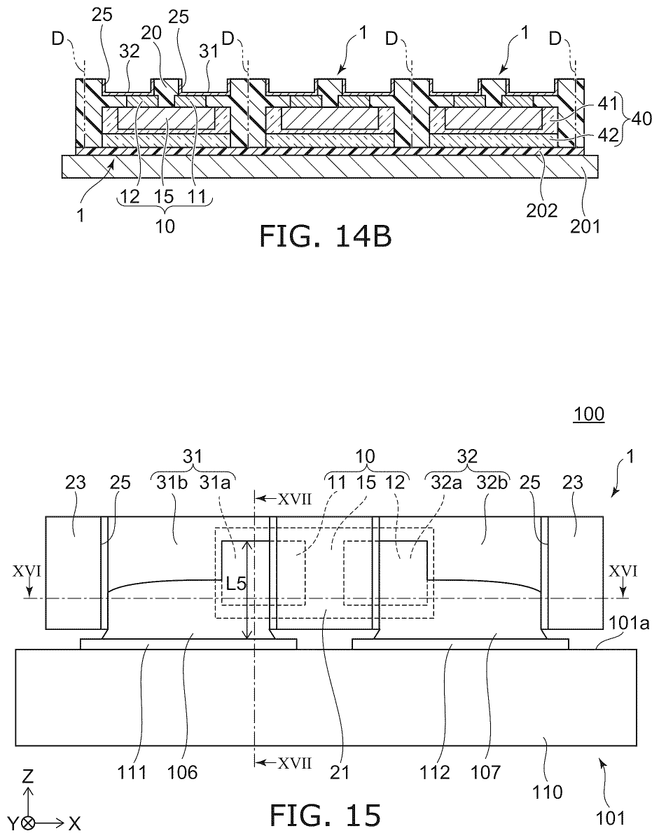

Then, as shown in FIGS. 14A and 14B, the covering member 20 is cut along a cutting line D to divide into each light-emitting element 10. At this time, the light-transmitting member 40 and the light-emitting element 10 are not exposed at the cross section of the covering member 20. Then, the support substrate 201 is removed by dissolving the adhesive layer 202. Thus, the light-emitting device 1 according to the present embodiment is manufactured.

Continuing, a light-emitting module 100 according to the present embodiment will now be described with reference to FIGS. 15 to 17. The light-emitting module 100 according to the present embodiment includes the light-emitting device 1, the substrate 101, a first connection member 106, and a second connection member 107. The configuration of the light-emitting device 1 is as described above. The substrate 101 includes a mounting surface 101a. The light-emitting device 1 is located on the mounting surface 101a of the substrate 101.

The substrate 101 includes a wiring substrate 110, a first terminal 111, and a second terminal 112. The wiring substrate 110 is a substrate in which wiring parts are located inside and/or at the surface of an insulating body. The first terminal 111 and the second terminal 112 are positioned on the mounting surface 101a of the substrate 101. The first terminal 111 and the second terminal 112 are connected respectively to wiring parts of the wiring substrate 110. The first connection member 106 contacts the first terminal 111 of the substrate 101 and the first metal film 31 of the light-emitting device 1. The second connection member 107 contacts the second terminal 112 of the substrate 101 and the second metal film 32 of the light-emitting device 1. The first connection member 106 and the second connection member 107 are, for example, solder.

The first metal film 31 of the light-emitting device 1 is connected to the first terminal 111 via the first connection member 106. Similarly, the second metal film 32 is connected to the second terminal 112 via the second connection member 107. Accordingly, the light-emitting device 1 is mechanically fixed to the substrate 101, and the light-emitting element 10 of the light-emitting device 1 is connected to the wiring parts of the wiring substrate 110.

As described above, the surface roughness of the portion 31a of the first metal film 31 covering the first conductive member 11 is less than the surface roughness of the portion 31b of the first metal film 31 covering the second covering part 22. Therefore, the wettability of the first connection member 106 for the portion 31a covering the first conductive member 11 is better than the wettability of the first connection member 106 for the portion 31b covering the second covering part 22. Accordingly, the first connection member 106 wets and spreads more easily on the portion 31a covering the first conductive member 11 than the portion 31b covering the second covering part 22.

Accordingly, as shown in FIG. 15, the first metal film 31 includes a first portion 31a covering the first conductive member 11. The first portion 31a includes a first region contacting the first connection member 106. The first metal film 31 includes a second portion 31b covering the second covering part 22. The second portion 31b includes a second region contacting the first connection member 106. A first proportion of the first region in the first portion 31a is greater than a second proportion of the second region in the second portion 31b. A length L4 of the first connection member 106 in a fourth direction perpendicular to the mounting surface 101a of the substrate 101 has a maximum at the portion 31a of the first metal film 31 covering the first conductive member 11. According to the present embodiment, the fourth direction is substantially equivalent to the third direction Z.

Similarly, the second metal film 32 includes a third portion 32a covering the second conductive member 12. The third portion 32a includes a third region contacting the second connection member 107. The second metal film 32 includes a fourth portion 32b covering the second covering part 22. The fourth portion 32b includes a fourth region contacting the second connection member 107. A third proportion of the third region in the third portion 32a is greater than a fourth proportion of the fourth region in the second portion 32b. The length of the second connection member 107 in the fourth direction perpendicular to the mounting surface 101a has a maximum at the portion 32a of the second metal film 32 covering the second conductive member 12.

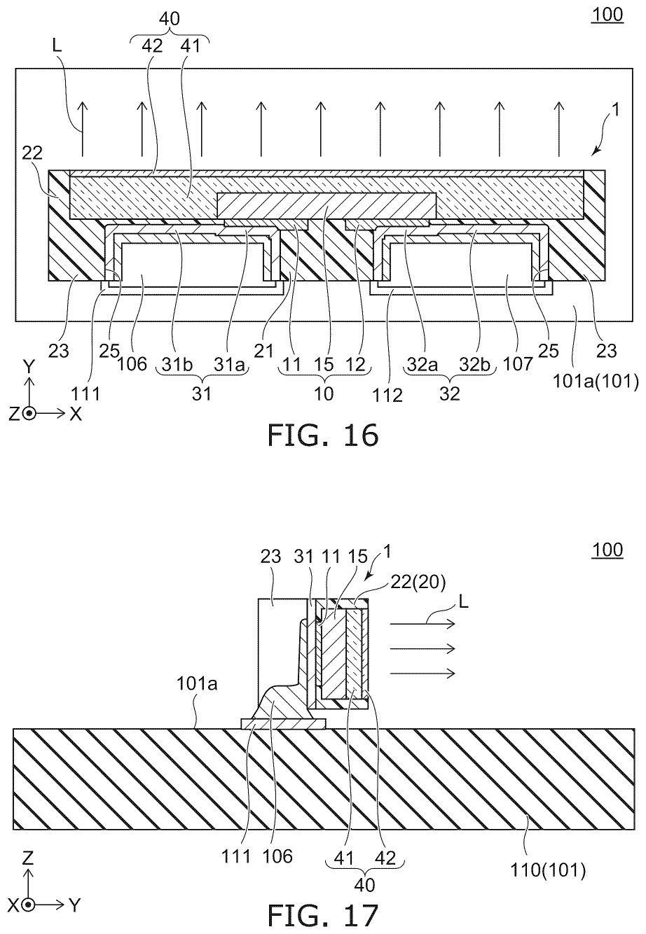

The first connection member 106 contacts the first terminal 111. The first connection member 106 is positioned at the entire region inside the recessed portion 25 when viewed in top-view. For example, the first connection member 106 is positioned at the entire region inside the recessed portion 25 when the cross-sectional view shown in FIG. 16 is viewed in top-view as viewed along the Z-direction. As shown in FIGS. 15 and 17, the first connection member 106 creeps along the first metal film 31 in the third direction Z. At this time, the first connection member 106 easily creeps further along the portion 31a covering the first conductive member 11 than the portion 31b covering the second covering part 22. For example, the first connection member 106 covers substantially the entire portion 31a of the first metal film 31 covering the first conductive member 11. Therefore, there are cases where a shape that reflects the outer edge of the first conductive member 11 appears in the outer edge of the first connection member 106 when viewed along the second direction Y This is similar for the second connection member 107 as well.

Effects of the present embodiment will now be described.

Although the first metal film 31, the first connection member 106, and the peripheral portions of the first metal film 31 and the first connection member 106 are mainly described in the following description of the effects, this is similar for the second metal film 32, the second connection member 107, and the peripheral portions of the second metal film 32 and the second connection member 107.

In the light-emitting device 1 according to the present embodiment, the covering member 20 preferably include the first covering part 21 and the second covering part 22, and the first metal film 31 preferably cover a portion of the first covering part 21. This can easily increase the area of the first metal film 31, so that the contact area between the first metal film 31 and the first connection member 106 is easily increased. This can increase the bonding strength between the first metal film 31 and the first connection member 106, and thus improve the bondability between the light-emitting device 1 and the substrate 101.

Also, in the second direction Y, the maximum length L1 of the first covering part 21 is preferably greater than the maximum length L2 of the first conductive member 11, and the maximum length L3 of the first metal film 31 is preferably greater than the maximum length L2 of the first conductive member 11. Accordingly, the first metal film 31 can be located on the side surface 21a of the first covering part 21, and the area of the first metal film 31 can easily be increased. This can increase the contact area between the first metal film 31 and the first connection member 106, and thus improve the bondability between the light-emitting device 1 and the substrate 101 is improved.

In the second direction Y, the maximum length L1 of the first covering part 21 is preferably not less than 2 times the maximum length L2 of the first conductive member 11. This can easily increase the area of the first metal film 31 located on the side surface 21a of the first covering part 21. The maximum length L1 of the first covering part 21 is preferably not more than 50 times the maximum length L2 of the first conductive member 11. This can easily make the light-emitting device 1 smaller in the second direction Y.

According to the present embodiment, in the second direction Y, the maximum length L3 of the first metal film 31 is preferably not less than 0.7 times the maximum length L1 of the first covering part 21. This can increase the area of the first metal film 31. In the second direction Y, the maximum length L3 of the first metal film 31 is preferably not more than 1.2 times the maximum length L1 of the first covering part 21. This can easily make the light-emitting device 1 smaller in the second direction Y.

In the second direction Y, the first covering part 21 preferably overlaps a portion of the first conductive member 11 and a portion of the second conductive member 12. This can easily make the distances of the first and second metal films 31 and 32 in the first direction X greater than the distances of the first and second conductive members 11 and 12 in the first direction X. This can suppress short-circuit between the first metal film 31 and the second metal film 32.

According to the present embodiment, it is favorable for the covering member 20 to include the third covering part 23, and for the light-transmitting member 40 to overlap the third covering part 23 in the second direction Y This can improve the mechanical strength of the covering member 20. The first metal film 31 preferably cover the side surface 23a of the third covering part 23. This can increase the area of the first metal film 31 is easily increased. Because the first covering part 21 and the third covering part 23 define portions of the recessed portion 25, the spreading area of the first connection member 106 tends to remain inside the recessed portion 25 when the first connection member 106 is bonded to the first metal film 31. This can suppress short-circuit between the first connection member 106 and the second connection member 107.

The maximum length L2 of the portion of the first conductive member 11 covered with the first covering part 21 is preferably not less than 1.5 times the maximum length L4 of the portion of the first conductive member 11 not covered with the first covering part 21. This can easily increase the contact area between the first conductive member 11 and the first metal film 31, so that it is easier to increase the bonding strength between the first conductive member 11 and the first metal film 31. The maximum length L2 of the portion of the first conductive member 11 covered with the first covering part 21 is preferably not more than 4 times the maximum length L4 of the portion of the first conductive member 11 not covered with the first covering part 21. This can easily make the light-emitting device 1 smaller in the second direction Y.

The recessed portion 25 preferably opens at the two ends of the covering member 20 in the third direction Z. Accordingly, it is easier to form the recessed portion 25, and it is easier to reduce the shape variation of the light-emitting device 1 than when the recessed portion 25 is open at only one end portion of the covering member 20. This can easily increase the yield of the light-emitting device 1.

The surface roughness of the portion 31a of the first metal film 31 covering the first conductive member 11 is preferably less than the surface roughness of the portion 31b of the first metal film 31 covering the second covering part 22. Accordingly, the first connection member 106 easily wets and spreads over the first metal film 31 at the portion 31a covering the first conductive member 11. Accordingly, the heat that is generated from the light-emitting element 10 can be easily dissipated efficiently to the first connection member 106 and the first terminal 111 via the first metal film 31 at the portion 31a covering the first conductive member 11.

A portion of the portion 31b of the first metal film 31 covering the second covering part 22 is preferably positioned further toward the +Z direction than the portion 31a of the first metal film 31 covering the first conductive member 11. As described above, the first connection member 106 wets and spreads relatively easily on the portion 31a, but does not wet and spread easily on the portion 31b; therefore, by providing the portion 31b further toward the +Z direction than the portion 31a, the first connection member 106 that wets and spreads over the portion 31a can easily suppress from wetting and spreading further by the portion 31b. This can easily suppress the first connection member 106 from reaching the upper surface 1U of the light-emitting device 1, and thus can easily make the light-emitting module 100 smaller in the second direction Y.

The portion 31a of the first metal film 31 covering the first conductive member 11 protrudes toward the −Y direction side with respect to the periphery of the portion 31a. This can easily suppress the first connection member 106 from wetting and spreading beyond the portion 31a covering the first conductive member 11. This can suppress the first connection member 106 from reaching the upper surface 1U of the light-emitting device 1, and thus reduce the size of the light-emitting module 100 in the second direction Y.

The light-transmitting member 40 preferably include the wavelength conversion layer 41 that includes a phosphor, and the light-transmitting layer 42 that does not include a phosphor, The wavelength conversion layer 41 is preferably separated from the external environment by the light-transmitting layer 42. This can reduce degradation due to moisture absorption by the phosphor inside the wavelength conversion layer 41.

A bonding resin may be located between the covering member 20 and the mounting surface 101a of the substrate 101. Accordingly, in addition to bonding the first metal film 31 and the first terminal 111 with the first connection member 106 and bonding the second metal film 32 and the second terminal 112 with the second connection member 107, the covering member 20 and the wiring substrate 110 can be bonded with the bonding resin. This can further improve the bonding strength between the substrate 101 and the light-emitting device 1. This similarly applies to the other embodiments described below as well.

### Second Embodiment

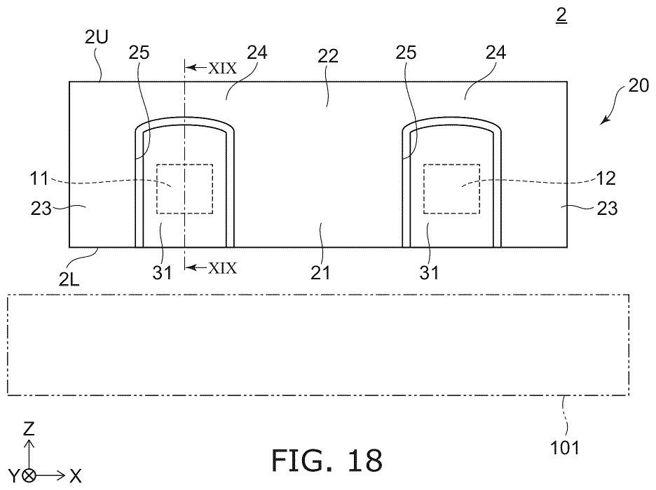

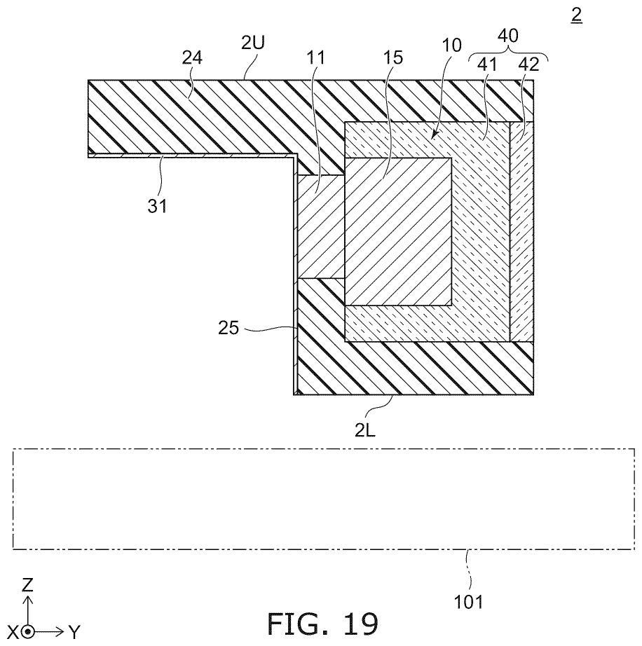

A light-emitting device 2 of a second embodiment will now be described with reference to FIGS. 18 and 19. In the light-emitting device 2 according to the present embodiment, the recessed portions 25 are open at a lower surface 2L of the light-emitting device 2, but are not open at an upper surface 2U of the light-emitting device 2. In other words, the covering member 20 includes two fourth covering parts 24 in addition to the first covering part 21, the second covering part 22, and the two third covering parts 23. The fourth covering parts 24 are positioned between the first covering part 21 and the third covering parts 23, and form portions of the upper surface 2U. The first metal film 31 and the second metal film 32 also are located on the lower surfaces of the fourth covering parts 24. Such a configuration can be achieved by forming discontinuous recessed portions that do not straddle the multiple light-emitting elements in the process shown in FIGS. 11A and 11B.

In the light-emitting device 2, the fourth covering parts 24 function as eaves that cover the upper ends of the recessed portions 25. Accordingly, the first connection member 106 and the second connection member 107 can be more reliably suppressed from creeping up to the upper surface 2U of the light-emitting device 2. This can reduce the size of the light-emitting module including the light-emitting device 2 in the third direction Z. Otherwise, the configuration, manufacturing method, and effects of the present embodiment are similar to those of the first embodiment.

### Third Embodiment

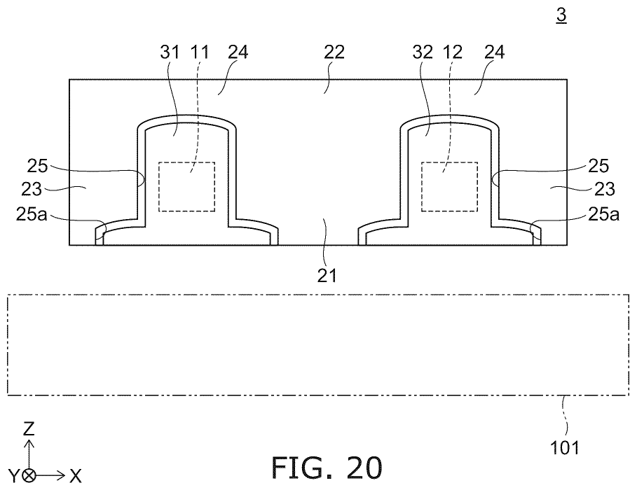

A light-emitting device 3 of a third embodiment will now be described with reference to FIG. 20. The light-emitting device 3 according to the present embodiment differs from the light-emitting device 2 according to the second embodiment in that the width in the first direction X of a lower end 25a of the recessed portion 25 is greater than the width in the first direction X of the portion other than the lower end of the recessed portion 25. Such a configuration can be achieved by forming the wide portion at the lower end 25a of the recessed portion 25 and forming the portion of the recessed portion 25 other than the lower end not simultaneously in the process shown in FIGS. 11A and 11B. By adjusting the blade tip, the recessed portion 25 that includes the wide portion at the lower end 25a of the recessed portion 25 and the portion of the recessed portion 25 other than the lower end may be formed by one half-cutting.

According to the present embodiment, by setting the width of the lower end 25a of the recessed portion 25 to be wide, the first connection member 106 and the second connection member 107 can contact the first and second terminals 111 and 112 with a larger area. This can further improve the bonding strength between the light-emitting device 3 and the substrate 101. Otherwise, the configuration, manufacturing method, and effects of the present embodiment are similar to those of the second embodiment.

As shown in FIG. 20, the wide portion of the lower end 25a of the recessed portion 25 may extend in both the +X direction and −X direction of the narrow portion that is other than the lower end of the recessed portion 25, and the wide portion of the lower end 25a of the recessed portion 25 may extend from one end portion of the narrow portion that is other than the lower end of the recessed portion 25. When the wide portion of the lower end 25a of the recessed portion 25 extends from one end portion of the narrow portion other than the lower end of the recessed portion 25, the wide portion of the lower end 25a of the recessed portion 25 positioned at the first conductive member 11 side preferably extends in the −X direction away from the second conductive member 12. This can easily suppress short-circuit of the light-emitting device. When the wide portion of the lower end 25a of the recessed portion 25 extends from one end portion of the narrow portion other than the lower end of the recessed portion 25, the wide portion of the lower end 25a of the recessed portion 25 positioned at the second conductive member 12 side preferably extends in the +X direction away from the first conductive member 11.

### Fourth Embodiment

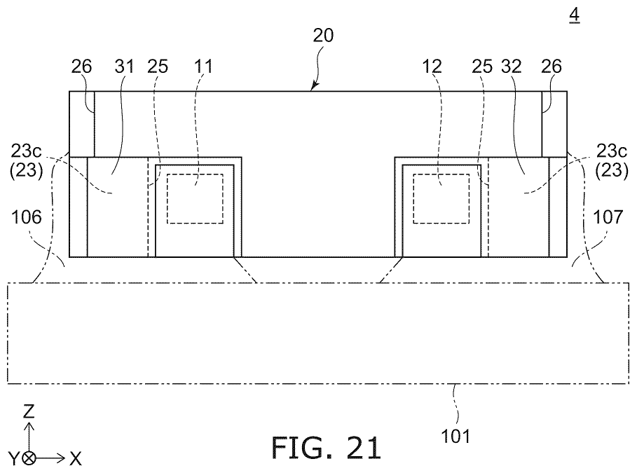

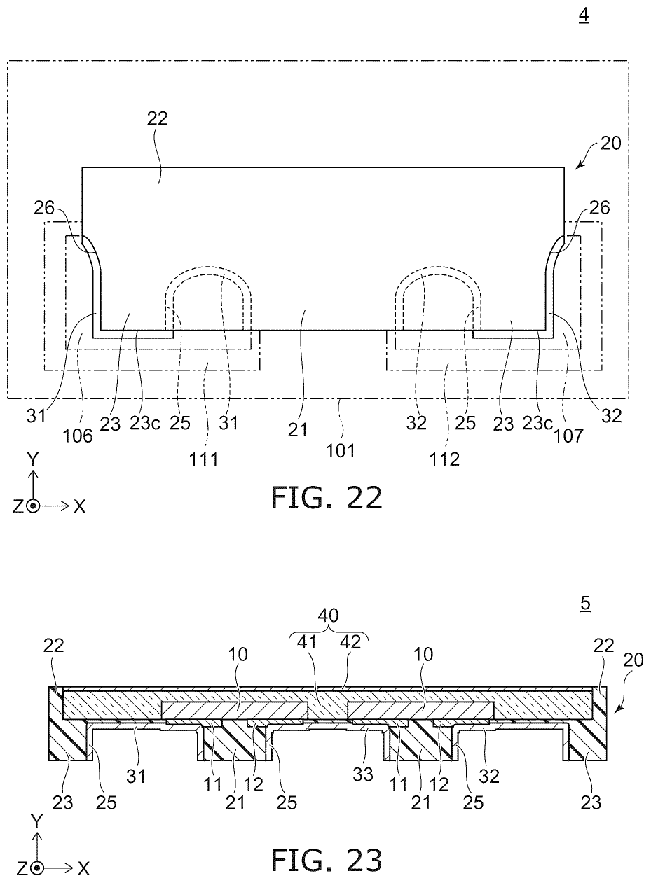

Alight-emitting device 4 of a fourth embodiment will now be described with reference to FIGS. 21 and 22. The light-emitting device 4 according to the present embodiment differs from the light-emitting device 2 according to the second embodiment in that a recessed portion 26 is formed between the side surface of the third covering part 23 facing the backside (the −Y direction side) and the side surface of the third covering part 23 facing the first direction X. The recessed portion 26 is formed over the full length of the covering member 20 in the third direction Z. The first metal film 31 and the second metal film 32 are located on aback surface 23c of the third covering part 23 and on the inner surface defining the recessed portion 26 in addition to the inner surface defining the recessed portion 25.

According to the present embodiment, the recessed portion 26 is provided, and the first metal film 31 and the second metal film 32 also are located on the back surface 23c of the third covering part 23 and on the inner surface defining the recessed portion 26, and thus can easily increase the areas of the first and second metal films 31 and 32. This can easily increase the contact area between the first metal film 31 and the first connection member 106 and the contact area between the second metal film 32 and the second connection member 107. This can easily increase the bonding strength between the light-emitting device 4 and the substrate 101. Otherwise, the configuration, manufacturing method, and effects of the present embodiment are similar to those of the second embodiment.

### Fifth Embodiment

A light-emitting device 5 of a fifth embodiment will now be described with reference to FIG. 23. The light-emitting device 5 according to the present embodiment includes two light-emitting elements 10. The two light-emitting elements 10 are arranged to be separated from each other along the first direction X. The peak wavelengths of the light emitted by the two light-emitting elements 10 may be equal or may be different from each other. Only one light-transmitting member 40 is included, and the light-transmitting member 40 faces the two light-emitting elements 10.

The covering member 20 includes two first covering parts 21. Accordingly, three recessed portions 25 are defined in the covering member 20. The first metal film 31 is located on the inner surface defining the recessed portion 25 located furthest toward the −X direction side, and is connected to the first conductive member 11 of the light-emitting element 10 located at the −X direction side. The second metal film 32 is located on the inner surface defining the recessed portion 25 located furthest toward the +X direction side, and is connected to the second conductive member 12 of the light-emitting element 10 located at the +X direction side.

A third metal film 33 is located on the inner surface defining the recessed portion 25 located at the center in the first direction X. The third metal film 33 is connected to the second conductive member 12 of the light-emitting element 10 located at the −X direction side and the first conductive member 11 of the light-emitting element 10 located at the +X direction side. The film configuration and film thickness of the third metal film 33 are substantially the same as those of the first and second metal films 31 and 32. Accordingly, the two light-emitting elements 10 are connected in series.

According to the present embodiment, the two light-emitting elements 10 can be included inside one light-emitting device 5. Accordingly, the intensity of the light emitted from the light-emitting device 5 is increased. Otherwise, the configuration, manufacturing method, and effects of the present embodiment are similar to those of the first embodiment.

### Sixth Embodiment

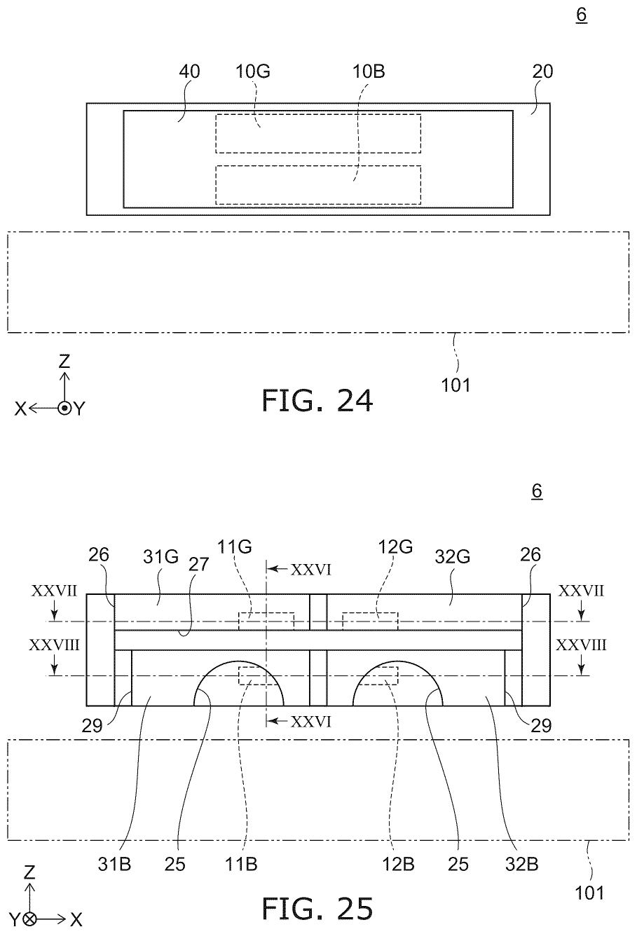

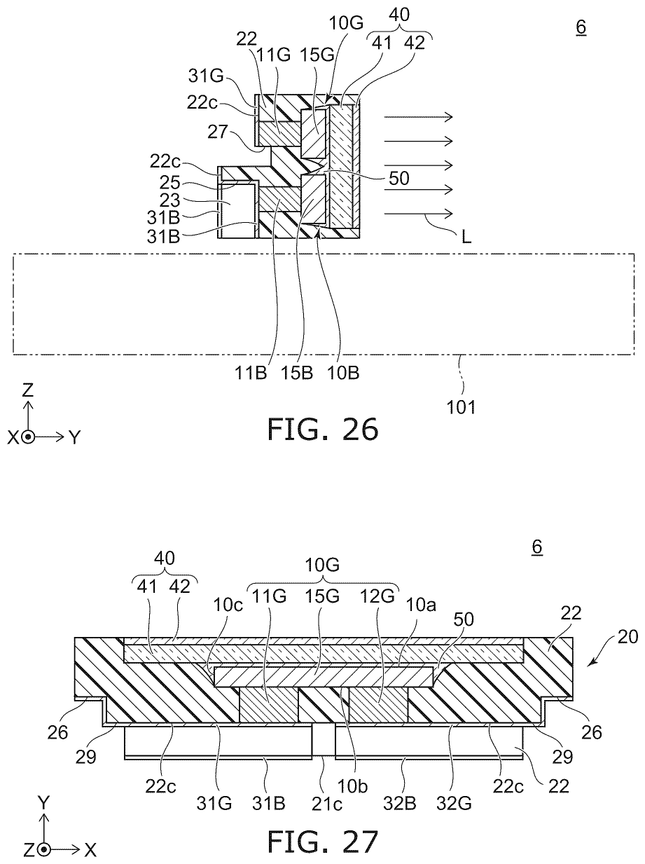

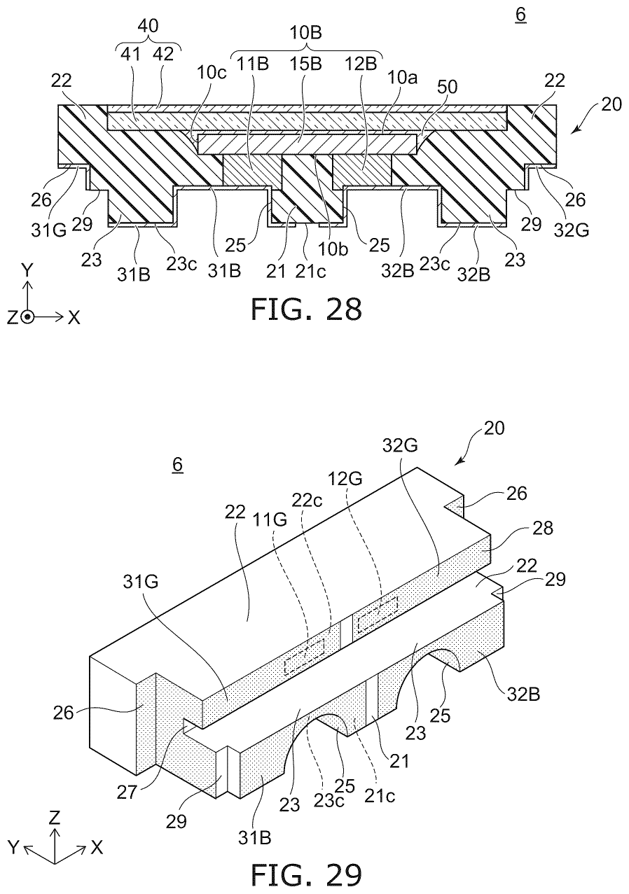

A light-emitting device 6 of a sixth embodiment will now be described with reference to FIGS. 24 to 29. In FIG. 29, a first metal film 31G, a second metal film 32G, a first metal film 31B, and a second metal film 32B are marked with dot patterns for easier viewing of the drawing.

As shown in FIGS. 24 to 29, the light-emitting device 6 according to the present embodiment differs from the light-emitting device 1 according to the first embodiment in that two light-emitting elements 10G and 10B are included. The light-emitting element 10G is, for example, an LED emitting green light, and the light-emitting element 10B is, for example, an LED emitting blue light. The light-emitting element 10G is positioned higher than the light-emitting element 10B. However, the light-emitting element 10G may be positioned lower than the light-emitting element 10B. The light-emitting element 10G includes a semiconductor stacked body 15G, a first conductive member 11G, and a second conductive member 12G. The light-emitting element 10B includes a semiconductor stacked body 15B, a first conductive member 11, and a second conductive member 12B.

The light-emitting device 6 according to the present embodiment includes the light-emitting element 10G that emits green light, and the light-emitting element 10B that emits blue light, and can independently control the light-emitting element 10G and the light-emitting element 10B. The color of the light emitted from the light-emitting device 6 can be controlled thereby.

The shape of the covering member 20 of the light-emitting device 6 is different from that of the light-emitting device 1. In the light-emitting device 6, the first and third covering parts 21 and 23 of the covering member 20 are located only at the lower side, i.e., the light-emitting element 10B side, of the light-emitting device 6, and are not located at the upper side, i.e., the light-emitting element 10G side, of the light-emitting device 6. The second covering part 22 is located at both the lower side and upper side of the light-emitting device 6. The recessed portion 26 that extends in the third direction Z is formed between the surface of the second covering part 22 facing the −Y direction and the surfaces of the second covering part 22 facing the two sides in the first direction X. A recessed portion 27 that extends in the first direction X is formed in the back surface, i.e., the surface facing −Y direction, of the second covering part 22.

The light-emitting device 6 includes the first metal film 31G that contacts the first conductive member 11G, the second metal film 32G that contacts the second conductive member 12G, the first metal film 31B that contacts the first conductive member 11, and the second metal film 32B that contacts the second conductive member 12B. One common light-transmitting member 40 is provided for the light-emitting elements 10G and 10B. The light-transmitting member 40 includes the wavelength conversion layer 41 and the light-transmitting layer 42. The wavelength conversion layer 41 includes, for example, a base material formed of a transparent resin material, and a phosphor that emits red light.

The first metal film 31G and the second metal film 32G are located on portions of a back surface 22c of the second covering part 22 and on the inner surfaces defining the recessed portions 26. The first metal film 31B and the second metal film 32B are located on a portion of the back surface 21c of the first covering part 21, a portion of the back surface 23c of the third covering part 23, and the inner surfaces defining the recessed portions 25. Metal films are not located on the inner surface defining the recessed portion 27 or on the inner surfaces defining recessed portions 29. In other words, the inner surface that defines the recessed portion 27 and the inner surfaces that define the recessed portions 29 are not covered with metal films. Accordingly, the first metal film 31B and the first metal film 31G can be separated, and the second metal film 32B and the second metal film 32G can be separated. The recessed portion 27 extends in the first direction X, and is formed of one outer edge of the covering member 20 positioned at the lower side of the light-emitting device 6 to the other outer edge of the covering member 20 positioned at the side opposite to the one outer edge of the covering member 20. The recessed portion 29 extends in the third direction Z, and is formed of one outer edge of the covering member 20 positioned at the lower side of the light-emitting device 6 to the other outer edge of the covering member 20 positioned at the side opposite to the one outer edge of the covering member 20. The depth of the recessed portion 27 from the back surface 21c of the first covering part 21 is greater than the depth of the recessed portion 29 from the back surface 21c of the first covering part 21.

The light-emitting device 6 may further include a light guide member 50. The light guide member 50 covers the entire first surface 10a and at least a portion of the third surface 10c of each of the light-emitting elements 10G and 10B (hereinbelow, also collectively referred to as the “light-emitting element 10”). In other words, a portion of the light guide member 50 is located between the light-emitting element 10 and the light-transmitting member 40, and another portion of the light guide member 50 is located on the third surface 10c of the light-emitting element 10.

The thickness of a portion of the light guide member 50 located on the third surface 10c of the light-emitting element 10 increases toward the light-transmitting member 40, and the side surface of this portion is oblique to the YZ-plane. Accordingly, the light that is emitted from the side surface of the light-emitting element 10 and enters the light guide member 50 can be reflected by the side surface of the light guide member 50 and guided toward the light-transmitting member 40.

For example, the light guide member 50 is formed of a transparent resin material. The resin material included in the light guide member 50 may be the same type of resin material as the base material of the light-transmitting member 40. The light guide member 50 also may include a light-diffusing material. The refractive index of the light guide member 50 may be set to be greater than the refractive index of the light-transmitting member 40 and less than the refractive index of the light-emitting element 10. Accordingly, the refractive index can be reduced in stages along the path of the light from the light-emitting element 10 to the light-transmitting member 40 via the light guide member 50, thereby efficiently propagating the light.

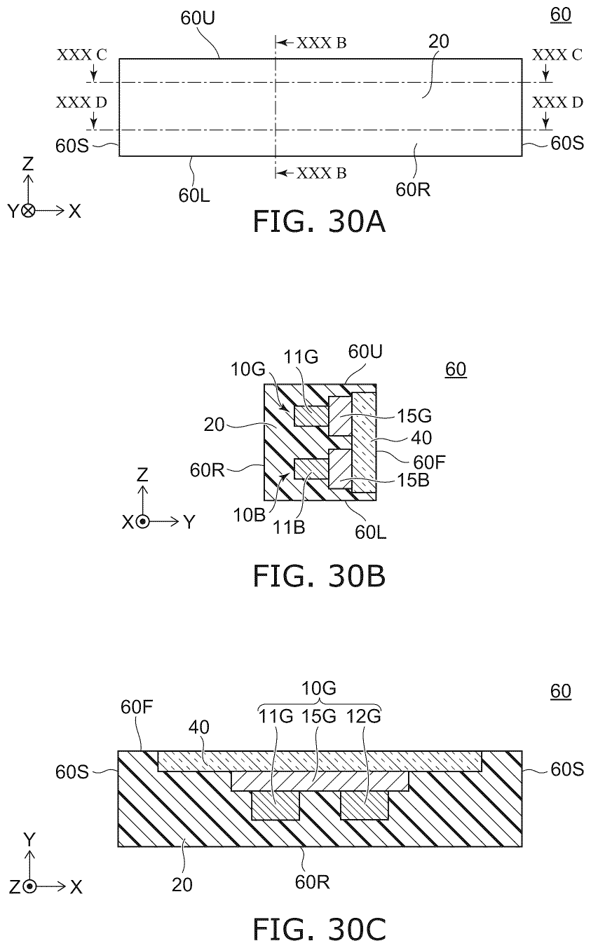

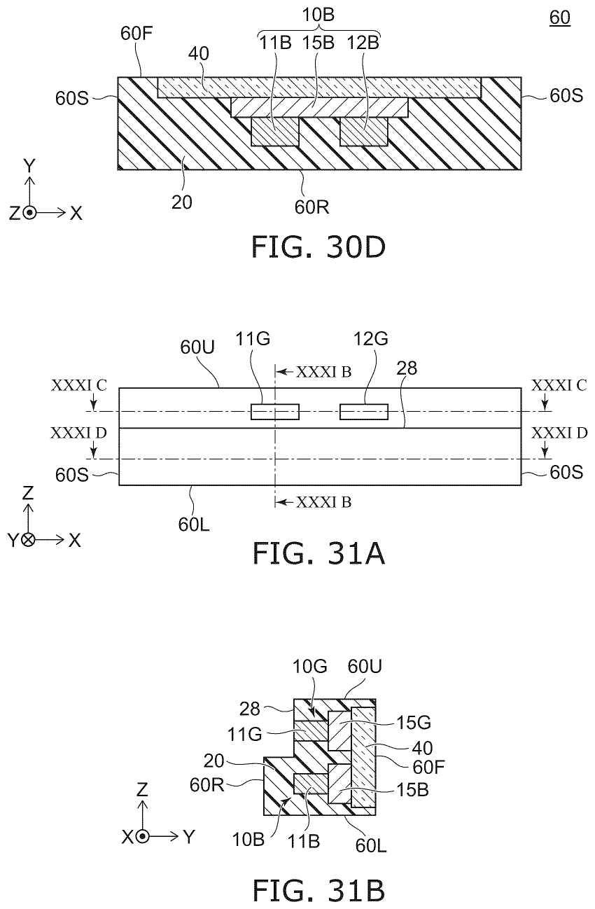

A method for manufacturing the light-emitting device 6 according to the present embodiment will now be described with reference to FIGS. 30A to 37D. The light guide member 50 is not illustrated in FIGS. 30A to 37D.

First, a structure body 60 is prepared as shown in FIGS. 30A to 30D. The structure body 60 includes the light-emitting elements 10G and 10B, the light-transmitting member 40, the light guide member 50, and the covering member 20. The structure body 60 has a rectangular parallelepiped shape including a front surface 60F, a back surface 60R, two side surfaces 60S, an upper surface 60U, and a lower surface 60L. In the specification, “rectangular parallelepiped shape” means not only a rectangular parallelepiped shape, but also shapes that can be considered to be substantially rectangular parallelepiped-shaped even when some distortions, irregular-shaped portions, etc., occur. The rectangular parallelepiped shape of the specification also includes a rectangular parallelepiped having beveled corners and edges, and a rectangular parallelepiped having rounded corners and edges.

The light-emitting elements 10G and 10B, the light-transmitting member 40, and the light guide member 50 are located inside the covering member 20. The light-emitting elements 10G and 10B are bonded to one major surface of the light-transmitting member 40 via the light guide member 50. The other major surface of the light-transmitting member 40 is not covered with the covering member 20 at the front surface 60F of the structure body 60. The surface of the structure body 60 other than the portion at which the light-transmitting member 40 is not covered with the covering member 20 is formed by the covering member 20.

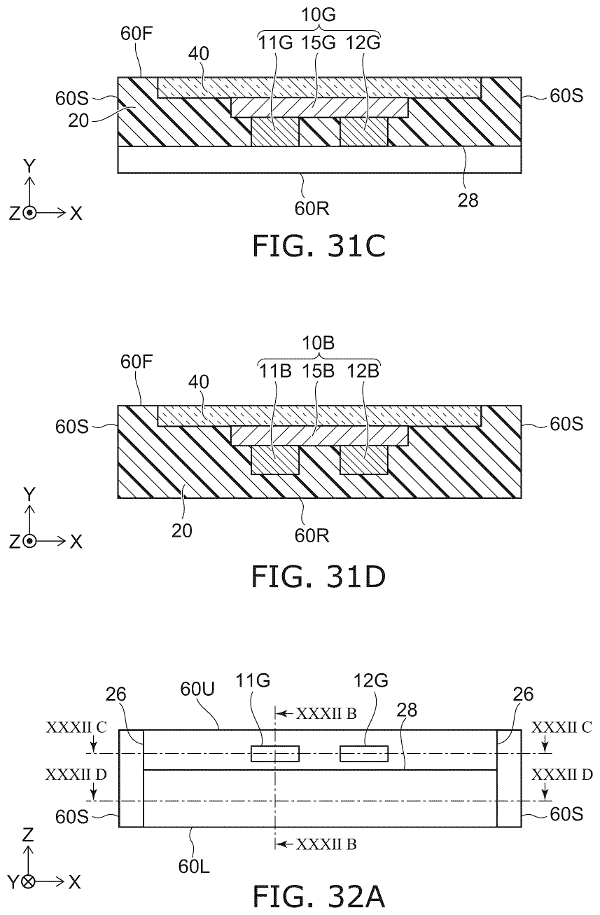

Then, as shown in FIGS. 31A to 31D, a portion of the covering member 20 positioned between the upper surface 60U and the back surface 60R is removed. Accordingly, a recessed portion 28 is formed in the covering member 20. The recessed portion 28 has a rectangular parallelepiped shape in which the first direction X is the longitudinal direction. The first conductive member 11G and the second conductive member 12G are exposed from under the covering member 20 at the inner surface defining the recessed portion 28.

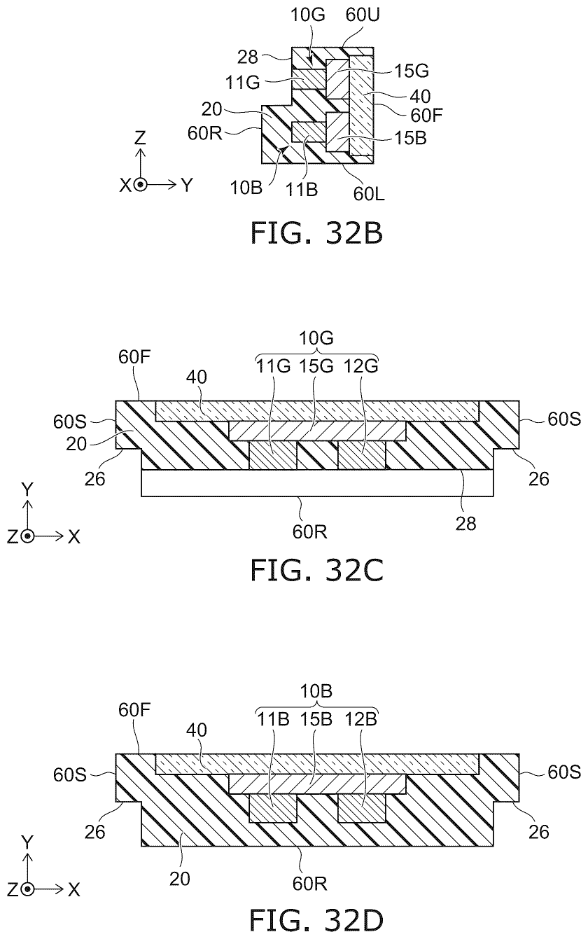

Continuing as shown in FIGS. 32A to 32D, portions of the covering member 20 positioned between the back surface 60R and the side surfaces 60S are removed. Accordingly, two recessed portions 26 are formed. Each recessed portion 26 has a rectangular parallelepiped shape in which the third direction Z is the longitudinal direction, and each recessed portion 26 reaches the upper surface 60U and the lower surface 60L.

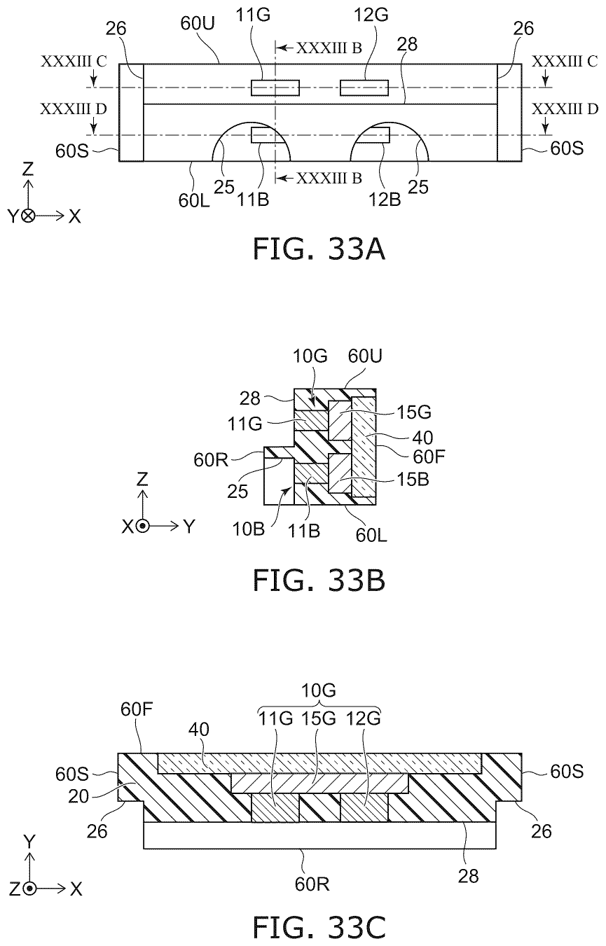

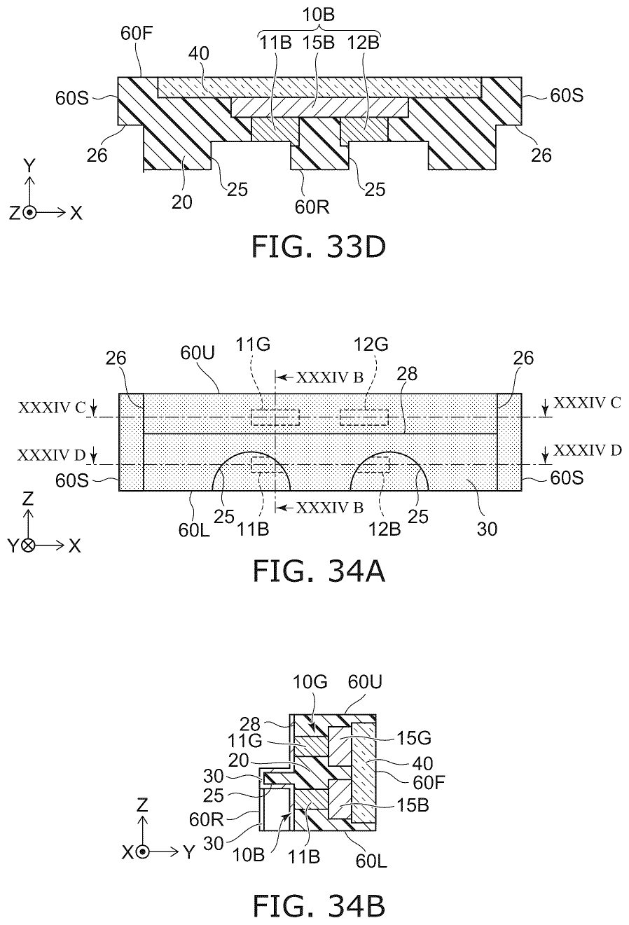

Then, as shown in FIGS. 33A to 33D, a portion of the covering member 20 positioned between the back surface 60R and the lower surface 60L is removed. Accordingly, the two recessed portions 25 are formed in the covering member 20. For example, each recessed portion 25 has a semicylindrical shape in which the second direction Y is the axis direction. A portion of the first conductive member 11B and a portion of the second conductive member 12B are exposed from under the covering member 20 at the bottom surface defining the recessed portion 25.

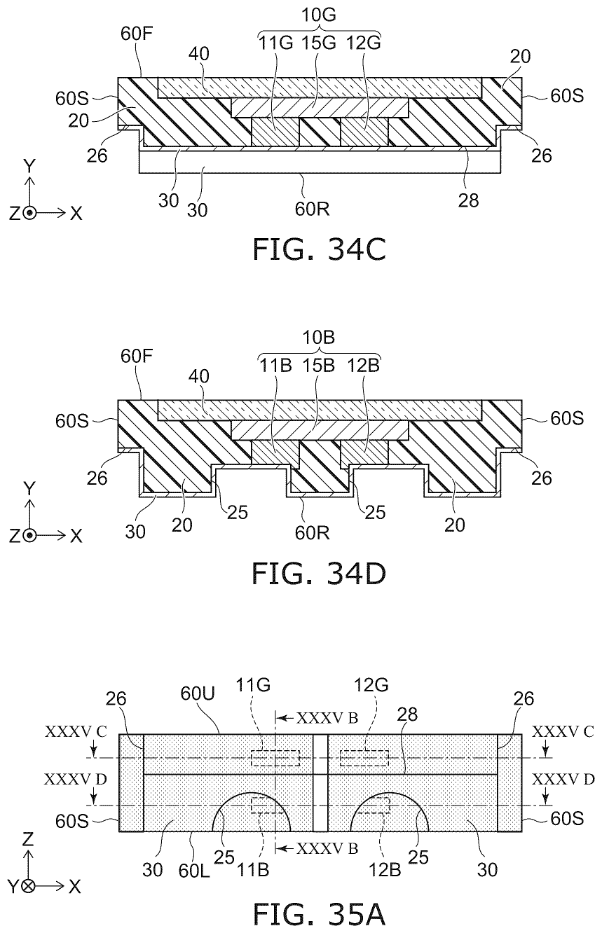

Continuing as shown in FIGS. 34A to 34D, the metal film 30 is formed by depositing a metal material from the back surface 60R side of the structure body 60. For example, a (Ni/Ru/Au) three-layer film may be formed by sputtering nickel, ruthenium, and gold, or a (Ni/Au) two-layer film may be formed by sputtering nickel and gold. The metal film 30 is located on the surface at the back surface 60R side of the covering member 20, on the inner surfaces defining the recessed portions 25, on the inner surfaces defining the recessed portions 26, and on the inner surface defining the recessed portion 28. The metal film 30 contacts the first conductive members 11G and 11B and the second conductive members 12G and 12B.

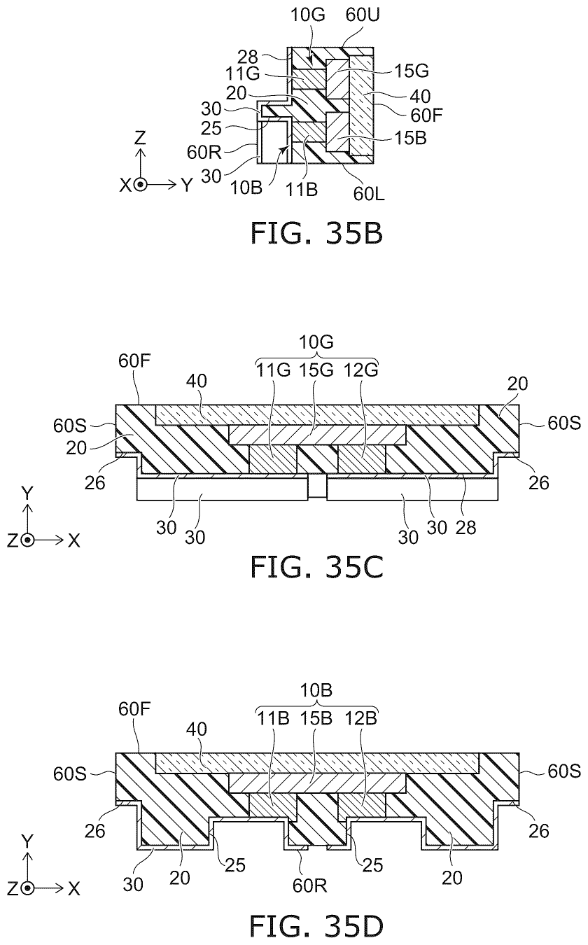

Then, as shown in FIGS. 35A to 35D, for example, the portion of the metal film 30 positioned at the center in the first direction X is removed by laser ablation. Accordingly, the metal film 30 is separated into the portion contacting the first conductive members 11G and 11B and the portion contacting the second conductive members 12G and 12B.

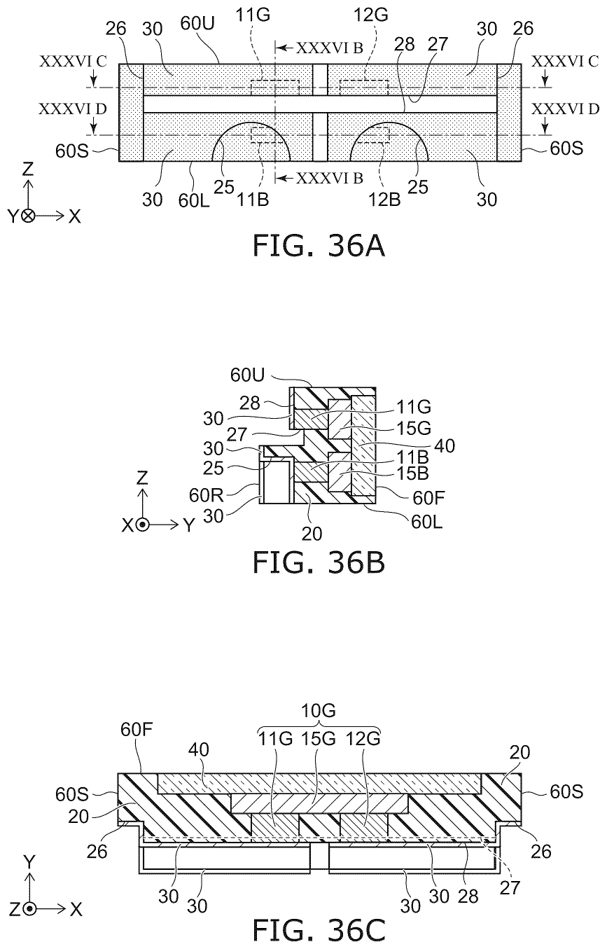

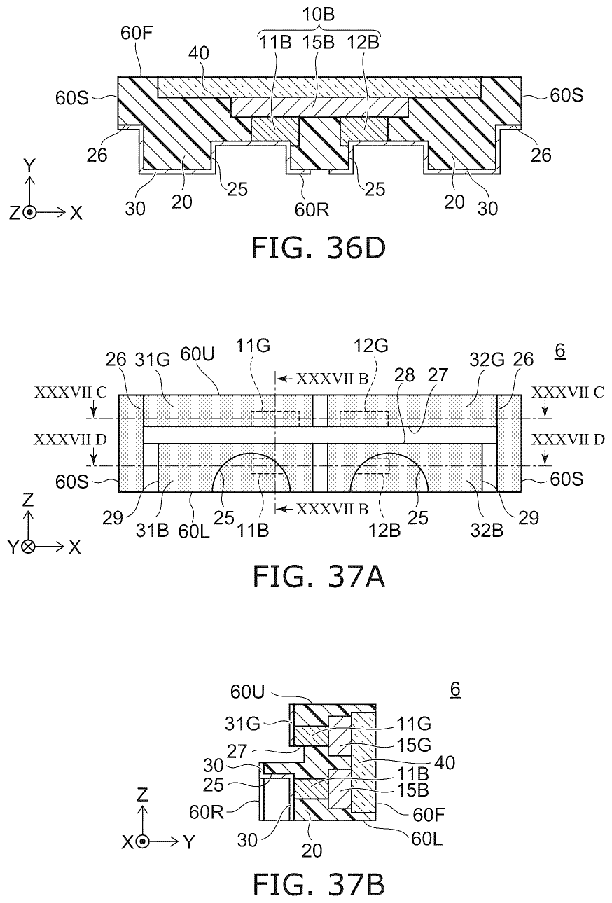

Continuing as shown in FIGS. 36A to 36D, the metal film 30 and the covering member 20 are removed by half-cutting or the like at the central portion in the third direction Z of the back surface 60R of the structure body 60. Accordingly, the recessed portion 27 is formed in the covering member 20. The recessed portion 27 has a rectangular parallelepiped shape in which the first direction X is the longitudinal direction. The recessed portion 27 reaches the two side surfaces 60S. The metal film 30 is removed from the region in which the recessed portion 27 is formed.

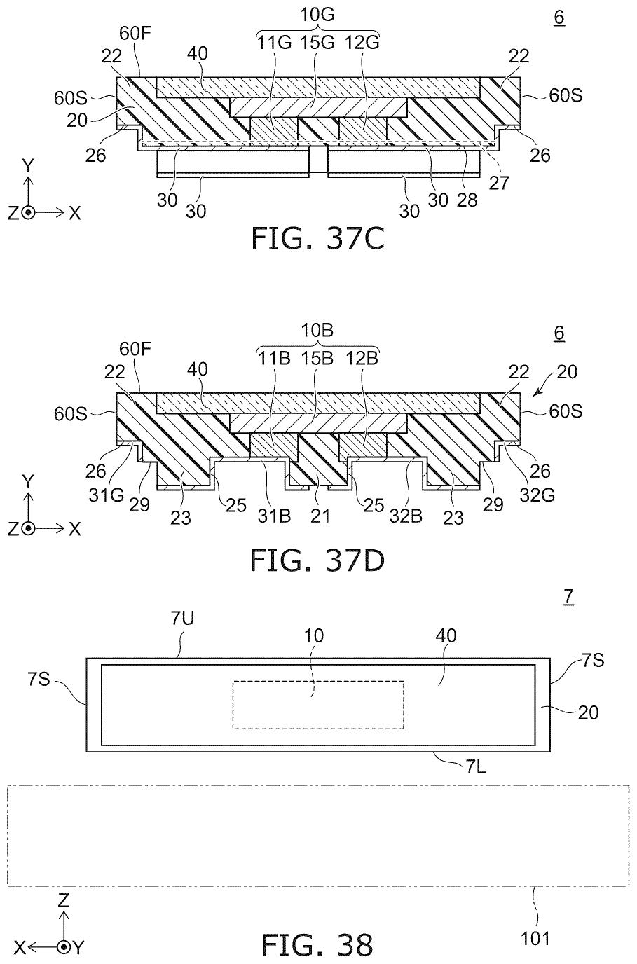

Then, as shown in FIGS. 37A to 37D, the metal film 30 and the covering member 20 are removed by half-cutting or the like in the region between the recessed portion 26 and the region of the back surface 60R of the structure body 60 lower than the recessed portion 27. Accordingly, the recessed portion 29 is formed in the covering member 20. The recessed portion 29 has a rectangular parallelepiped shape in which the third direction Z is the longitudinal direction. The metal film 30 is removed from the region in which the recessed portion 29 is formed. The upper end of the recessed portion 29 reaches the recessed portion 28, and the lower end of the recessed portion 29 reaches the lower surface 60L.

The metal film 30 is separated into the first metal film 31G, the second metal film 32G, the first metal film 31B, and the second metal film 32B by the processes shown in FIGS. 35A to 37D. The first metal film 31G contacts the first conductive member 11G of the light-emitting element 10G. The second metal film 32G contacts the second conductive member 12G of the light-emitting element 10G. The first metal film 31B contacts the first conductive member 11B of the light-emitting element 10B. The second metal film 32B contacts the second conductive member 12B of the light-emitting element 10B. Thus, the light-emitting device 6 is manufactured.

In the light-emitting device 6 according to the present embodiment, the first metal film 31B and the second metal film 32B are located on the inner surfaces defining the recessed portions 25, on the back surface of the first covering part 21, and on the back surfaces of the third covering parts 23. The first metal film 31G and the second metal film 32G also are located on the inner surfaces defining the recessed portions 26 and on the back surface of the second covering part 22. Accordingly, it is easier to increase the contact areas between the metal films and the connection members while ensuring the insulation between the metal films. Accordingly, it is easy to increase the bonding strength between the light-emitting device 6 and the substrate 101. Otherwise, the configuration, manufacturing method, and effects of the present embodiment are similar to those of the first embodiment.

### Seventh Embodiment

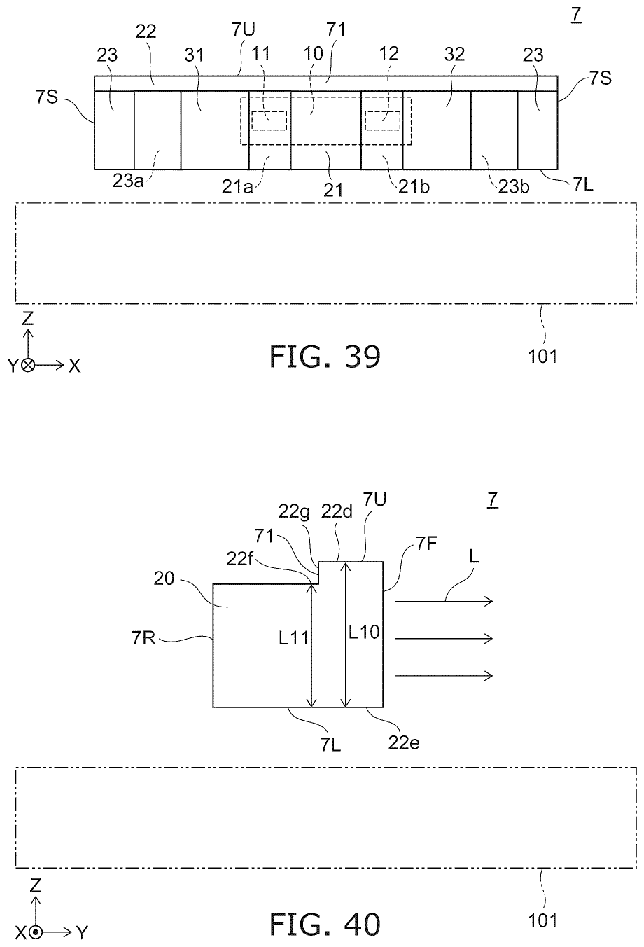

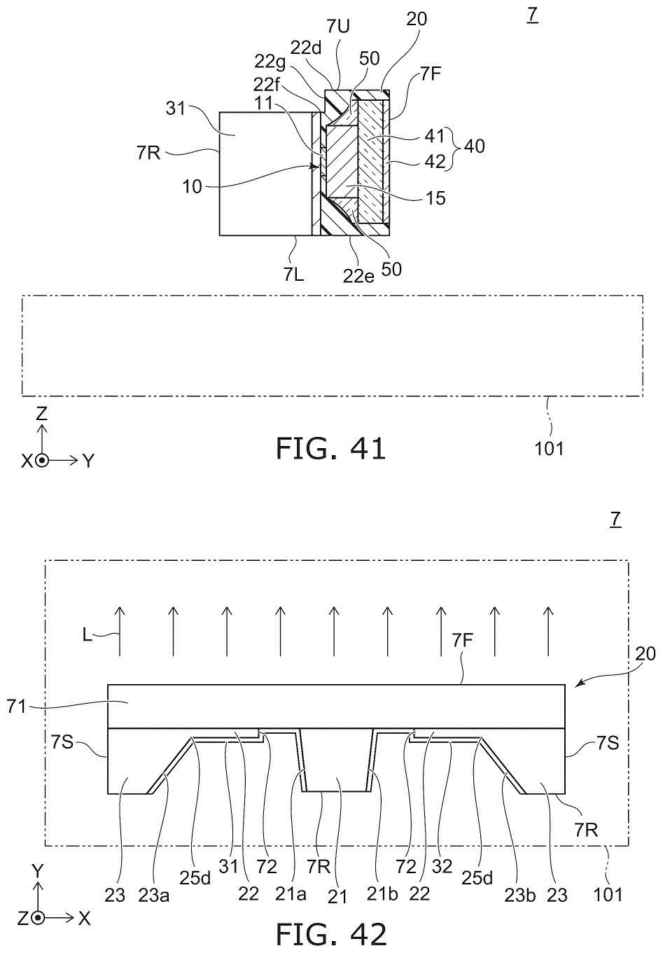

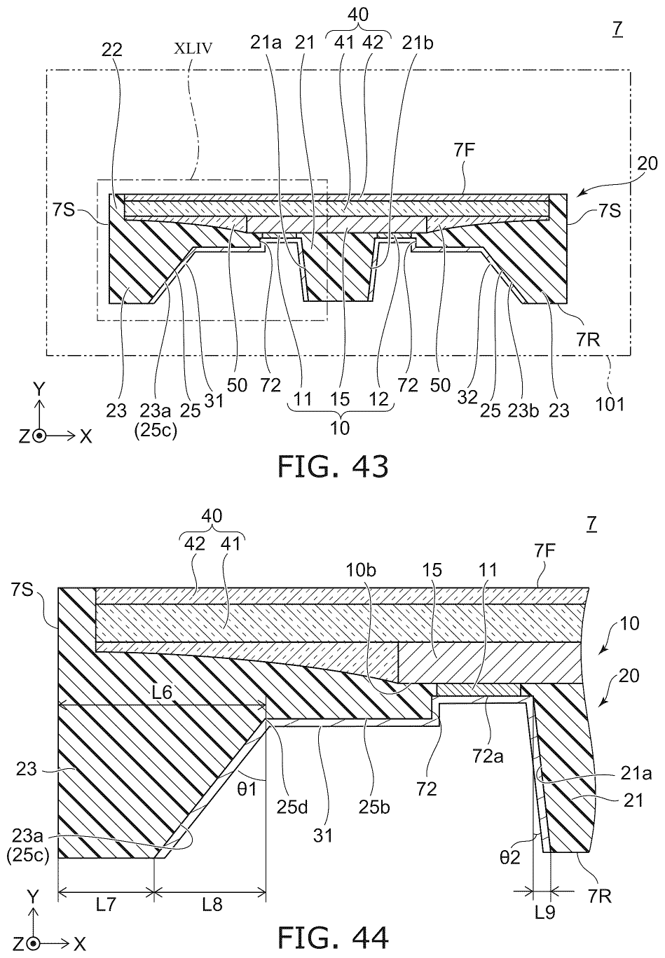

A light-emitting device 7 of a seventh embodiment will now be described with reference to FIGS. 38 to 45. The light-emitting device 7 according to the present embodiment differs from the light-emitting device 1 according to the first embodiment in that the second covering part 22 of the covering member 20 includes a first outer surface 22d, a second outer surface 22e, a third outer surface 22f, and a connecting surface 22g; the side surfaces 23a and 23b of the third covering part 23 and the side surfaces 21a and 21b of the first covering part 21 are oblique to the YZ-plane; the light guide member 50 is provided on the third surface 10c of the light-emitting element 10; a portion of the second covering part 22 covers a portion of the second surface 10b of the light-emitting element 10; a groove 72 is provided in the portion of the second covering part 22 covering the second surface 10b; the first and second conductive members 11 and 12 of the light-emitting element 10 are exposed at a portion of a bottom surface 72a defining the groove 72; and the first metal film 31 and the second metal film 32 are provided over the entire bottom surface 72a defining the groove 72.

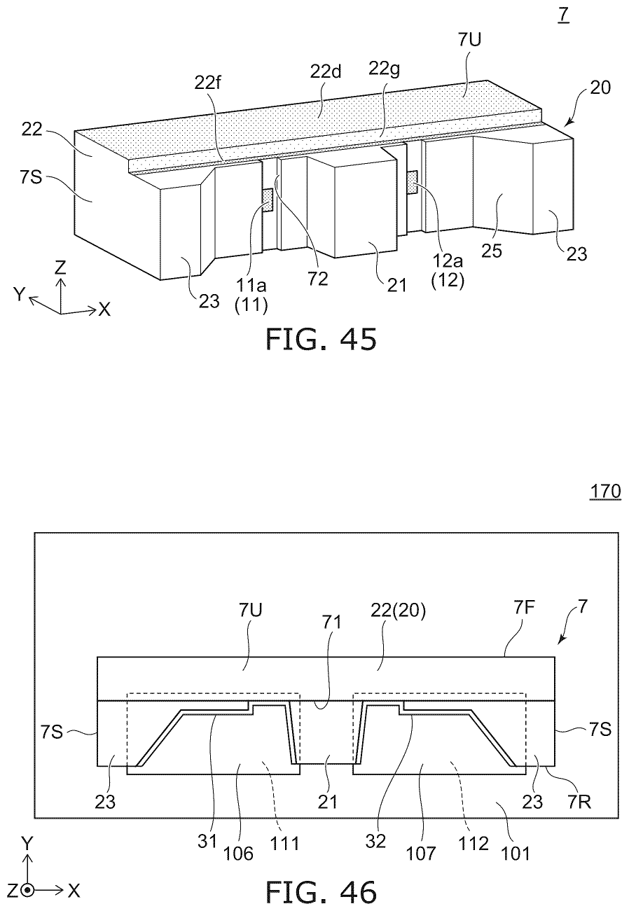

The first metal film 31 and the second metal film 32 are not illustrated in FIG. 45 for easier viewing of the drawing. The first outer surface 22d, the third outer surface 22f, the connecting surface 22g, an exposed portion 11a of the first conductive member 11 (described below), and an exposed portion 12a of the second conductive member 12 (described below) are marked with hatching.

First, the second covering part 22 of the covering member 20 will be described.

The second covering part 22 includes the first outer surface 22d overlapping the third surface 10c of the light-emitting element 10 in the third direction Z, the second outer surface 22e positioned at the side opposite to the first outer surface 22d, the third outer surface 22f overlapping the first and second conductive members 11 and 12 in the third direction Z, and the connecting surface 22g connecting the first outer surface 22d and the third outer surface 22f.

According to the embodiment, the first outer surface 22d, the third outer surface 22f, and the connecting surface 22g of the second covering part 22 form an upper surface 7U of the light-emitting device 7. For example, the first outer surface 22d and the third outer surface 22f are substantially parallel to the XY-plane, and the connecting surface 22g is tilted with respect to the XY-plane, e.g., substantially parallel to the XZ-plane. The second outer surface 22e of the second covering part 22 form a lower surface 7L of the light-emitting device 7.

A length L10 from the first outer surface 22d to the second outer surface 22e in the third direction Z is greater than a length L11 from the third outer surface 22f to the second outer surface 22e in the third direction Z. In other words, L10>L11.

The first metal film 31 and the second metal film 32 are positioned to be separated from the first outer surface 22d. The first metal film 31 and the second metal film 32 may contact the second outer surface 22e, or may be positioned to be separated from the second outer surface 22e. At least a portion of the connecting surface 22g is not covered with the first metal film 31 or the second metal film 32. For example, the entire first outer surface 22d, the third outer surface 22f, and the connecting surface 22g are not covered with the first metal film 31 or the second metal film 32.

In other words, the covering member 20 includes a recessed portion 71. The recessed portion 71 is positioned at the end portion of the light-emitting device 7 at the +Z direction side in the third direction Z, and is provided at the corner between the upper surface 7U and a back surface 7R of the light-emitting device 7. The recessed portion 71 extends in the first direction X, extends through the covering member 20 in the first direction X, and reaches side surfaces 7S of the light-emitting device 7 at both sides in the first direction X. The recessed portion 71 does not reach a front surface 7F of the light-emitting device 7. The exterior shape of the recessed portion 71 is, for example, rectangular when viewed in back-view. The light-emitting element 10 and the light-transmitting member 40 are not exposed at the connecting surface 22g and the third outer surface 22f that define the inner surface of the recessed portion 71. According to the present embodiment, the first metal film 31 and the second metal film 32 are not located at the connecting surface 22g and the third outer surface 22f that define the inner surface of the recessed portion 71. Therefore, the entire inner surface of the recessed portion 71 is formed of the covering member 20.

The side surface of the third covering part 23 and the side surface of the first covering part 21 will now be described.

According to the present embodiment, the side surface 23a of the one third covering part 23 is oblique to the side surface 7S of the light-emitting device 7, i.e., the YZ-plane, so that the side surface 23a separates from the first covering part 21 away from the light-transmitting member 40. That is, the side surface 23a of one third covering part 23 is oblique to the YZ-plane so that the side surface 23a separates from the first covering part 21 toward the −Y direction. An angle θ1 between the side surface 7S of the light-emitting device 7 and the side surface 23a of the third covering part 23 is, for example, not less than 5° and not more than 80°.

Accordingly, a length L6 of the third covering part 23 in the first direction X at the side proximate to the light-emitting element 10 in the second direction Y is greater than a length L7 of the third covering part 23 in the first direction X at the side distant to the light-emitting element 10 in the second direction Y In other words, L6>L7. The side of the third covering part 23 distant to the light-emitting element 10 is, for example, the distal portion of the third covering part 23, and the side of the third covering part 23 proximate to the light-emitting element 10 is, for example, the base portion of the third covering part 23.

The boundary between the second covering part 22 and the third covering part 23 can be defined as the XZ-plane including a boundary 25d between a bottom surface 25b defining the recessed portion 25 and a side surface 25c defining the recessed portion 25. The bottom surface 25b that defines the recessed portion 25 is formed of the second covering part 22. The side surface 25c that defines the recessed portion 25 is the side surfaces 23a and 23b of the third covering part 23. The boundary 25d is a bent portion of the inner surface defining the recessed portion 25. The side surface 23a of the third covering part 23 may be a curved surface. When there is no distinct bent portion between the second covering part 22 and the third covering part 23, the boundary 25d may be defined as the portion at which the curvature at the concave surface of the inner surface defining the recessed portion 25 has a maximum. The side surface 7S of the light-emitting device 7, i.e., the outer surface at the side opposite to the side surface 23a or the side surface 23b of the third covering part 23, may be oblique to the YZ-plane.

Similarly, the side surface 23b of the other third covering part 23 is also oblique to the side surface 7S of the light-emitting device 7 so that the side surface 23b separates from the first covering part 21 away from the light-transmitting member 40. The angle between the side surface 7S of the light-emitting device 7 and the side surface 23b of the third covering part 23 also is θ1.

The side surface 21a of the first covering part 21 is oblique to the side surface 7S of the light-emitting device 7 so that the side surface 21a separates from the opposing third covering part 23 away from the light-transmitting member 40. That is, the side surface 21a of the first covering part 21 is oblique to the YZ-plane so that the side surface 21a separates from the third covering part 23 toward the −Y direction. An angle θ2 between the side surface 7S of the light-emitting device 7 and the side surface 21a of the first covering part 21 is less than the angle θ1. In other words, θ2<θ1. The angle θ2 is, for example, not less than 0° and not more than 60°. Therefore, a length L9 of the side surface 21a in the first direction X is less than a length L8 of the side surface 23a in the first direction X. In other words, L9<L8.

Similarly, the side surface 21b of the first covering part 21 is also oblique to the side surface 7S of the light-emitting device 7 so that the side surface 21b separates from the opposing third covering part 23 away from the light-transmitting member 40. The angle between the side surface 7S of the light-emitting device 7 and the side surface 21b of the first covering part 21 is also θ2. Thus, the tilts of the side surfaces defining the recessed portion 25 are asymmetric.

The light guide member 50 will now be described.

The light guide member 50 is located on the surface of the wavelength conversion layer 41 at the −Y direction side and on the third surface 10c of the light-emitting element 10. The light guide member 50 may also be located between the light-emitting element 10 and the wavelength conversion layer 41. Otherwise, the configuration of the light guide member 50 is as described in the sixth embodiment.

The groove 72 and the periphery of the groove 72 will now be described.

In the light-emitting device 7, a portion of the second covering part 22 covers a portion of the second surface 10b of the light-emitting element 10, and the grooves 72 are provided in the portion of the second covering part 22 covering the second surface 10b. Two grooves 72 are provided in the covering member 20, and one groove 72 is positioned in the bottom surface 25b defining each recessed portion 25. The groove 72 extends through the second covering part 22 in the third direction Z, and reaches the lower surface 7L and the upper surface 7U of the light-emitting device 7. The groove 72 also reaches the third outer surface 22f.

The first and second conductive members 11 and 12 of the light-emitting element 10 respectively include the exposed portions 11a and 12a that are not covered with the second covering part 22 at the grooves 72. The exposed portion 11a is connected to the first metal film 31. The exposed portion 12a is connected to the second metal film 32. For example, the entire first conductive member 11 of the light-emitting element 10 is exposed at the bottom surface 72a defining one groove 72, and the entire second conductive member 12 of the light-emitting element 10 is exposed at the bottom surface 72a defining the other groove 72.

The first metal film 31 is provided over the entire inner surface defining one recessed portion 25. Therefore, the first metal film 31 is provided over the entire bottom surface 72a defining one groove 72. Accordingly, the portion of the first metal film 31 located on the bottom surface 72a defining the groove 72 includes a portion contacting the first conductive member 11 and a portion contacting the second covering part 22.

Similarly, the second metal film 32 is provided over the entire inner surface defining the other recessed portion 25. Therefore, the second metal film 32 is provided over the entire bottom surface 72a defining the other groove 72. Accordingly, the portion of the second metal film 32 located on the bottom surface 72a defining the groove 72 includes a portion contacting the second conductive member 12 and a portion contacting the second covering part 22.

A method for manufacturing the light-emitting device 7 will now be described.

For example, the covering member 20 is formed by a molding technique using a mold such as injection molding, transfer molding, compression molding, etc. The light-emitting element 10, the light-transmitting member 40, and the light guide member 50 are located inside the covering member 20. Also, the two recessed portions 25 are provided in the covering member 20. The side surfaces 23a and 23b of the third covering parts 23 of the covering member 20 are oblique so that the side surfaces 23a and 23b separate from the first covering part 21 toward the back surface 7R, and the side surfaces 21a and 21b of the first covering part 21 are oblique so that the side surfaces 21a and 21b separate from the opposing third covering part 23 toward the back surface 7R; therefore, the releasability between the mold and the cured covering member 20 can be improved.

Then, the grooves 72 are formed in the bottom surfaces 25b defining the recessed portions 25 by griding the covering member 20 of a blade. Accordingly, the first and second conductive members 11 and 12 of the light-emitting element 10 are exposed at portions of the bottom surfaces 72a defining the grooves 72. Then, the first metal film 31 and the second metal film 32 are formed by a technique similar to the first embodiment. Then, the recessed portion 71 is formed by griding the covering member 20 with a blade. Accordingly, the third outer surface 22f and the connecting surface 22g are formed in the second covering part 22 as the inner surface of the recessed portion 71. The first metal film 31 and the second metal film 32 that are on the third outer surface 22f and on the connecting surface 22g are removed. Thus, the light-emitting device 7 is manufactured.

A light-emitting module 170 of a seventh embodiment will now be described with reference to FIG. 46.

The light-emitting module 170 includes the substrate 101, the first connection member 106, the second connection member 107, and the light-emitting device 7. In the light-emitting device 7, the first metal film 31 and the second metal film 32 are not located on the inner surface of the recessed portion 71, i.e., on the third outer surface 22f and on the connecting surface 22g of the second covering part 22. Therefore, even when the first connection member 106 is located on the entire surface of the first metal film 31 and the second connection member 107 is located on the entire surface of the second metal film 32, the first connection member 106 and the second connection member 107 do not penetrate the recessed portion 71 of which the inner surface is defined by the connecting surface 22g and the third outer surface 22f. Accordingly, the first connection member 106 and the second connection member 107 are not located at the upper surface 7U of the light-emitting device 7.

At least a portion of the connecting surface 22g is preferably not covered with the first metal film 31. Accordingly, the connecting surface 22g being not covered with the first metal film 31 can facilitate control of the shape of the first connection member 106 wetting and spreading over the first metal film 31. The portion of the connecting surface 22g not covered with the first metal film 31 preferably reach the side surfaces 7S of the light-emitting device 7 at both sides in the first direction X. Accordingly, the first connection member 106 and the second connection member 107 can be easily suppressed from being located on the upper surface 7U of the light-emitting device 7.

Effects of the embodiment will now be described.

In the light-emitting device 7 according to the embodiment, the second covering part 22 includes the third outer surface 22f and the connecting surface 22g, and the first metal film 31 and the second metal film 32 are not located on the third outer surface 22f or on the connecting surface 22g. Therefore, the first connection member 106 and the second connection member 107 can be suppressed from reaching the upper surface 7U when mounting the light-emitting device 7 to the substrate 101. Accordingly, the light-emitting device 7 can be smaller in the first and third directions X and Z while suppressing short-circuits between the first connection member 106 and the third connection member 107.

In the light-emitting device 7, the length L6 of a first portion 23e in the first direction X is greater than the length L7 of a second portion 23f in the first direction X. Accordingly, the strength of the third covering part 23 is high, and the rigidity of the entire covering member 20 is high. Accordingly, warp of the light-emitting device 7 can be suppressed.

In the light-emitting device 7, the side surfaces 23a and 23b of the third covering part 23 and the side surfaces 21a and 21b of the first covering part 21 are oblique. The releasability between the covering member 20 and the mold can be improved thereby.

In the light-emitting device 7, the first conductive member 11 is exposed at a portion of the bottom surface 72a defining the groove 72, and the first metal film 31 is provided over the entire bottom surface 72a defining the groove 72. Accordingly, the entire surface of the first conductive member 11 facing the −Y direction side contacts the first metal film 31, and the electrical resistance between the first conductive member 11 and the first metal film 31 can be reduced. Similarly, the electrical resistance between the second conductive member 12 and the second metal film 32 can be reduced. Otherwise, the configuration, manufacturing method, and effects of the embodiment are similar to those of the first embodiment.

### Eighth Embodiment

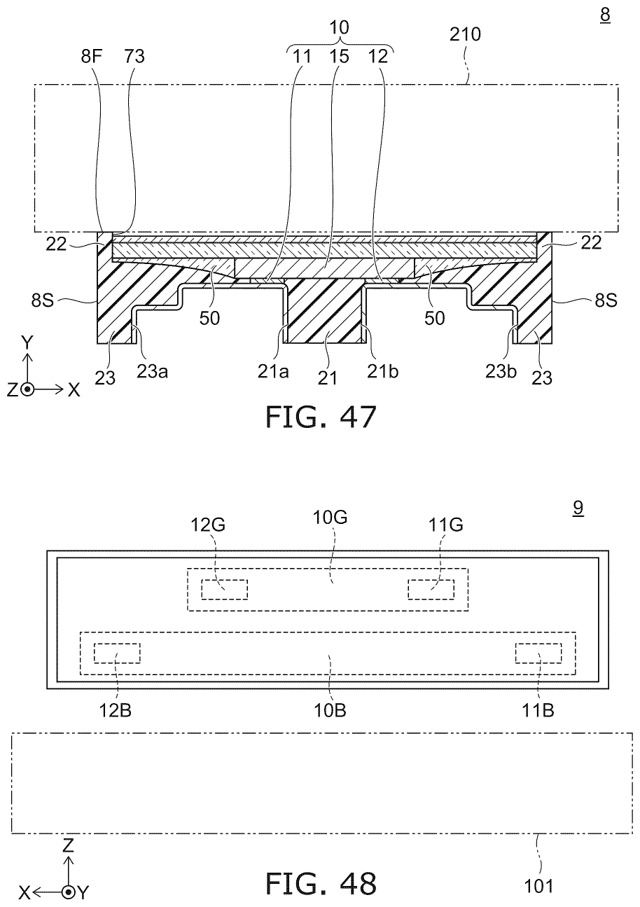

A light-emitting device 8 of an eighth embodiment will now be described with reference to FIG. 47. The light-emitting device 8 according to the present embodiment differs from the light-emitting device 7 according to the seventh embodiment in that the side surfaces 23a and 23b of the third covering parts 23 have staircase shapes, the side surfaces 21a and 21b of the first covering part 21 are not oblique to side surfaces 8S of the light-emitting device 8, the groove 72 is not formed, the light-transmitting member 40 is recessed with respect to the covering member 20 at a front surface 8F of the light-emitting device 8, and a recessed portion 73 is formed in the front surface 8F.

According to the embodiment, the recessed portion 73 formed in the front surface 8F of the light-emitting device 8 can allow the light-transmitting member 40 not to easily contact external members, and thus the light-emitting device 8 is not easily damaged. Also, an air layer is formed inside the recessed portion 73 when the front surface 8F of the light-emitting device 8 is bonded to alight guide plate 210. Uneven color of the light emitted from the light-emitting device 8 is reduced thereby. Otherwise, the configuration, manufacturing method, and effects of the embodiment are similar to those of the first embodiment. In other embodiments above or below as well, the recessed portion 73 may be provided in the front surface of the light-emitting device to make the light-transmitting member 40 recessed with respect to the covering member 20.

### Ninth Embodiment

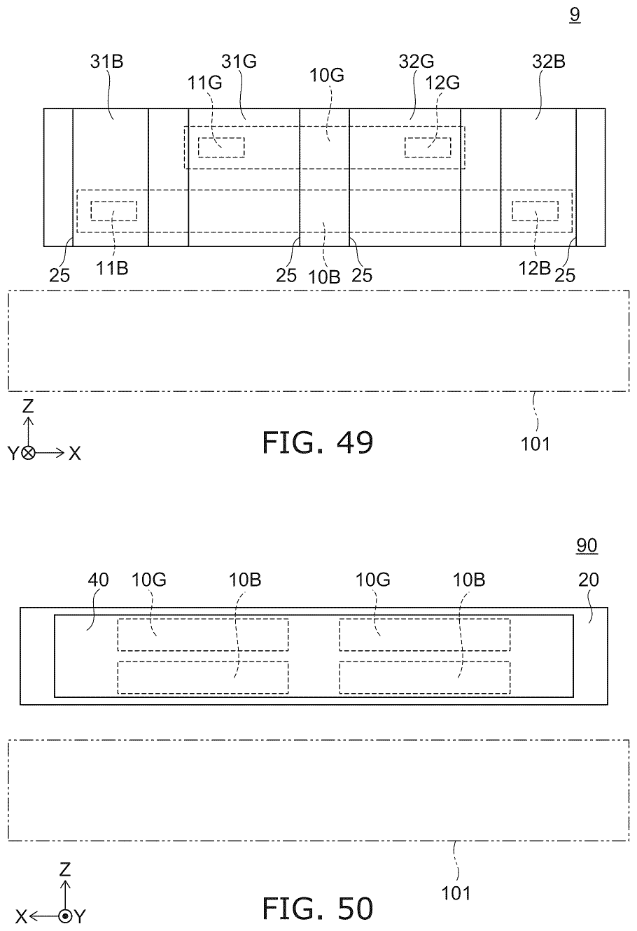

A light-emitting device 9 of a ninth embodiment will now be described with reference to FIGS. 48 and 49. The light-emitting device 9 according to the present embodiment differs from the light-emitting device 6 according to the sixth embodiment in that four recessed portions 25 are formed, and the length in the first direction X of the light-emitting element 10G, which emits green light, is less than the length in the first direction X of the light-emitting element 10B, which emits blue light.

According to the present embodiment, the length of the light-emitting element 10G in the first direction X is different from the length of the light-emitting element 10B in the first direction X, so that the first conductive member 11G of the light-emitting element 10G can be located at a different position from the first conductive member 11B of the light-emitting element 10B in the first direction X, and the second conductive member 12G of the light-emitting element 10G can be located at a different position from the second conductive member 12B of the light-emitting element 10B in the first direction X. Accordingly, the first conductive members 11G and 11B and the second conductive members 12G and 12B can be located inside different respective recessed portions 25 in the first direction X. Accordingly, the first conductive members 11G and 11B and the second conductive members 12G and 12B can be connected to the substrate 101 independently from one another.

According to the present embodiment, compared with the sixth embodiment, the shape of the covering member 20 can be simplified. Otherwise, the configuration, manufacturing method, and effects of the embodiment are similar to those of the sixth embodiment.

### Tenth Embodiment

Alight-emitting device 90 of a tenth embodiment will now be described with reference to FIG. 50. The light-emitting device 90 according to the embodiment differs from the light-emitting device 6 according to the sixth embodiment in that two light-emitting elements 10G that emit green light and two light-emitting elements 10B that emit blue light are included. The two light-emitting elements 10G are arranged with a space therebetween in the first direction X, and the two light-emitting elements 10B are arranged with a space therebetween in the first direction X.

According to the embodiment, when the target value of the peak wavelength of the light emitted from the light-emitting element 10B is λ_{B}, it is favorable to select, as the two light-emitting elements 10B, a light-emitting element 10B having a peak wavelength that is not less than the wavelength λ_{B}, and a light-emitting element 10B having a peak wavelength that is not greater than the wavelength λ_{B}. For example, the peak wavelengths of the two light-emitting elements 10B can be set to (λ_{B}+α) and (λ_{B}−α).

Specifically, when the target peak wavelength λ_{B} is 450 nm, a light-emitting element 10B having an actual measured peak wavelength value of 449 nm and a light-emitting element 10B having an actual measured peak wavelength value of 451 nm may be combined, a light-emitting element 10B having an actual measured peak wavelength value of 448 nm and a light-emitting element 10B having an actual measured peak wavelength value of 452 nm may be combined, or a light-emitting element 10B having an actual measured peak wavelength value of 447 nm and a light-emitting element 10B having an actual measured peak wavelength value of 453 nm may be combined.

Similarly, when the target value of the peak wavelength of the light emitted from the light-emitting element 10G is λ_{G}, it is preferable to select, as the two light-emitting elements 10G, a light-emitting element 10G having a peak wavelength that is not less than the wavelength λ_{G} and a light-emitting element 10G having a peak wavelength that is not greater than the wavelength λ_{G}. For example, the peak wavelengths of the two light-emitting elements 10G can be set to (λ_{G}+β) and (λ_{G}−β).

Specifically, when the target peak wavelength λ_{G} is 540 nm, a light-emitting element 10G having an actual measured peak wavelength value of 539 nm and a light-emitting element 10G having an actual measured peak wavelength value of 541 nm may be combined, a light-emitting element 10G having an actual measured peak wavelength value of 538 nm and a light-emitting element 10G having an actual measured peak wavelength value of 542 nm may be combined, or a light-emitting element 10G having an actual measured peak wavelength value of 537 nm and a light-emitting element 10G having an actual measured peak wavelength value of 543 nm may be combined.

According to the embodiment, the peak wavelength variation of the light-emitting elements can be compensated by combining two light-emitting elements of the same type. Otherwise, the configuration, manufacturing method, and effects of the embodiment are similar to those of the sixth embodiment.

### Eleventh Embodiment

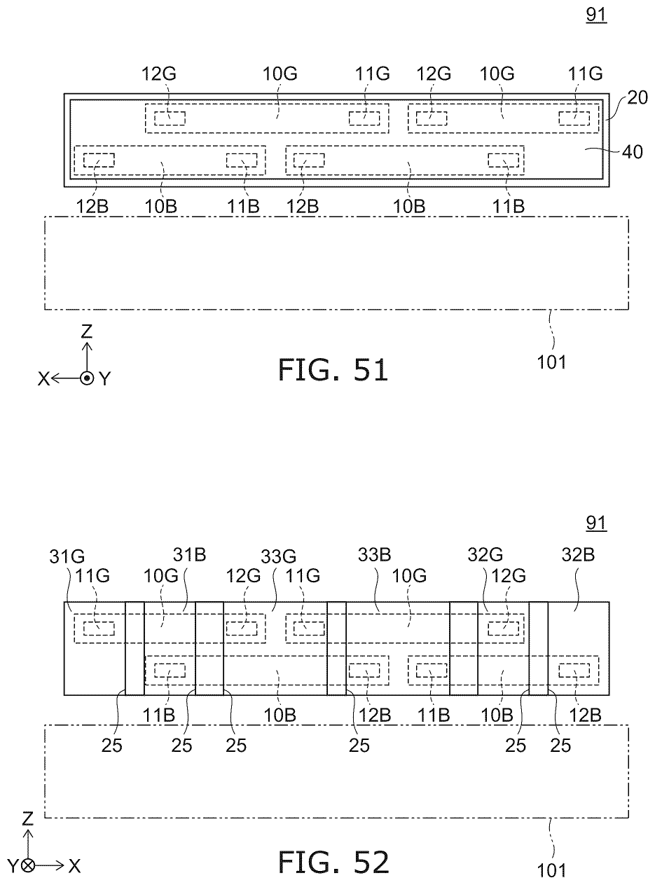

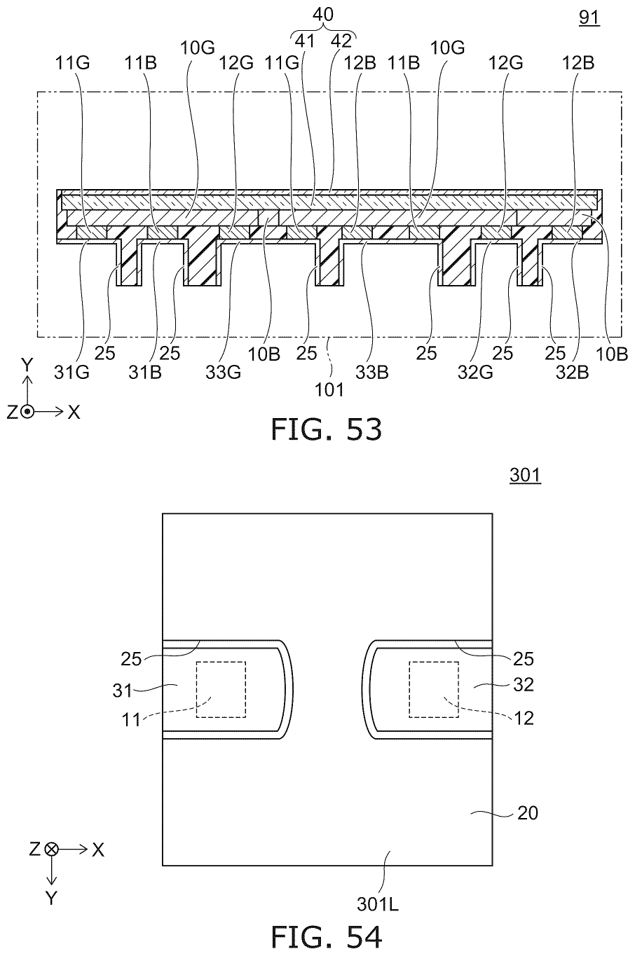

A light-emitting device 91 of an eleventh embodiment will now be described with reference to FIGS. 51 to 53. The light-emitting device 91 according to the embodiment differs from the light-emitting device 90 according to the tenth embodiment in that the lengths in the first direction X of the two light-emitting elements 10B are different from each other, and the lengths in the first direction X of the two light-emitting elements 10G are different from each other.

In the light-emitting device 91, the positions in the first direction X of the first and second conductive members 11B and 12B of the two light-emitting elements 10B and the first and second conductive members 11G and 12G of the two light-emitting elements 10G are different from one another. Six recessed portions 25 are provided in the covering member 20, and metal films are located on the inner surfaces defining the recessed portions 25.

The first conductive member 11B of one light-emitting element 10B is connected to a first connection member 106B via the first metal film 31B, the second conductive member 12B of the one light-emitting element 10B and the first conductive member 11B of another light-emitting element 10B are connected to each other via a third metal film 33n, and the second conductive member 12B of the other light-emitting element 10B is connected to a second connection member 107B via the second metal film 32B.

The first conductive member 11G of one light-emitting element 10G is connected to a first connection member 106G via the first metal film 31G, the second conductive member 12G of the one light-emitting element 10G and the first conductive member 11G of another light-emitting element 10G are connected to each other via a third metal film 33G, and the second conductive member 12G of the other light-emitting element 10G is connected to the second connection member 107G via the second metal film 32G. Accordingly, mutually independent currents can be provided to a circuit in which the two light-emitting elements 10B are connected in series and a circuit in which the two light-emitting elements 10G are connected in series.

According to the present embodiment, compared with the sixth embodiment, the shape of the covering member 20 can be simplified. Otherwise, the configuration, manufacturing method, and effects of the embodiment are similar to those of the tenth embodiment.

### Reference Examples

Several reference examples will now be described.

For example, the covering member 20 may include the second covering part 22 and the third covering part 23, and does not have to include the first covering part 21.

The covering member 20 may include the second covering part 22 and the fourth covering part 24, and does not have to include the first covering part 21 and the third covering part 23. In such a case, the fourth covering part 24 has an eave-like shape protruding toward the backside from the upper portion of the back surface of the second covering part 22.

The covering member 20 may be formed by forming the first covering part 21, the second covering part 22, and the third covering part 23 as separate bodies and then connecting the first covering part 21, the second covering part 22, and the third covering part 23 to each other.

Although an example is shown in the embodiments above in which the light-emitting device is lateral surface-emitting type, the light-emitting device may be top surface-emitting type.

FIG. 54 is a bottom view showing a top surface-emitting type of light-emitting device according to a reference example.

In the light-emitting device 301 according to the reference example as shown in FIG. 54, two recessed portions 25 are formed in a lower surface 301L, and the first metal film 31 and the second metal film 32 are located on the inner surfaces defining the recessed portions 25. The first metal film 31 is connected to the first conductive member 11, and the second metal film 32 is connected to the second conductive member 12. In the light-emitting device 301, the light-transmitting member 40 is exposed at the upper surface of the light-emitting device 301, and light is emitted above via the light-transmitting member 40.

The embodiments above are examples embodying the invention, and the invention is not limited to these embodiments. For example, additions, deletions, or modifications of some of the components or processes according to the embodiments above also are included in the invention. The embodiments above can be implemented in combination with each other.

For example, the invention can be utilized in a light source of a display device, etc.

Embodiments include the following aspects.

### Note 1

A light-emitting device, comprising:
a light-emitting element including a first surface, a second surface positioned at a side opposite to the first surface, and a plurality of third surfaces positioned between the first surface and the second surface, the light-emitting element comprising:
   a first conductive member and a second conductive member positioned at the second surface and arranged in a first direction;
a covering member comprising:
   a first covering part covering a region of the second surface between the first conductive member and the second conductive member, and
   a second covering part covering the plurality of third surfaces, wherein:
   the covering member does not cover at least a portion of the first conductive member and at least a portion of the second conductive member;
a first metal film covering a portion of the first covering part, the first metal film being electrically connected to the first conductive member; and
a second metal film separated from the first metal film, the second metal film covering a portion of the first covering part, the second metal film being electrically connected to the second conductive member; wherein:
in a second direction from the second surface toward the first surface, a maximum length of the first covering part is greater than a maximum length of the first conductive member, and a maximum length of the first metal film is greater than the maximum length of the first conductive member.

### Note 2

The device according to note 1, wherein:
in the second direction, the maximum length of the first covering part is not less than 2 times and not more than 50 times the maximum length of the first conductive member.

### Note 3

The device according to note 1 or 2, wherein:
in the second direction, the maximum length of the first metal film is not less than 0.7 times and not more than 1.2 times the maximum length of the first covering part.

### Note 4

The device according to any one of notes 1-3, wherein
the first covering part overlaps a portion of the first conductive member and a portion of the second conductive member in the second direction.

### Note 5

The device according to any one of notes 1-4, wherein:
the covering member further comprises a third covering part overlapping the first covering part in the first direction and overlapping the second covering part in the second direction; and
the first metal film covers at least a portion of the third covering part.

### Note 6

The device according to note 5, further comprising:
a light-transmitting member positioned between the second covering part and the third surface of the light-emitting element; wherein:
the third covering part overlaps the light-transmitting member in the second direction.

### Note 7

The device according to note 5 or 6, wherein:
a length of the third covering part in the first direction is longer at a side proximate to the light-emitting element in the second direction than at a side distant to the light-emitting element in the second direction.

### Note 8

The device according to any one of notes 5-7, wherein:
a recessed portion defined by the first and third covering parts is open at two ends of the covering member in a third direction that is orthogonal to the first and second directions.

### Note 9

The device according to any one of notes 1-8, wherein:
a portion of the first metal film covering the first conductive member protrudes with respect to a periphery.

### Note 10

The device according to any one of notes 1-9, wherein:
a surface roughness of a portion of the first metal film covering the first conductive member is less than a surface roughness of a portion of the first metal film covering the second covering part.

### Note 11

The device according to any one of notes 1-10, wherein:
the second covering part includes:
   a first outer surface overlapping at least a portion of the third surfaces in a third direction orthogonal to the first and second directions; and
   a second outer surface positioned at a side opposite to the first outer surface, and
the first metal film is positioned to be separated from the first outer surface.

### Note 12

The device according to note 11, wherein:
the second covering part includes:
   a third outer surface overlapping the first conductive member in the third direction; and
   a connecting surface connecting the first and third outer surfaces,
a length from the first outer surface to the second outer surface in the third direction is greater than a length from the third outer surface to the second outer surface in the third direction, and
at least a portion of the connecting surface is not covered with the first metal film.

### Note 13

The device according to any one of notes 1-12, wherein:
a portion of the second covering part covers a portion of the second surface;
a groove is provided in the portion of the second covering part that covers the portion of the second surface;
the first conductive member includes an exposed portion not covered with the second covering part in the groove; and
the exposed portion is electrically connected to the first metal film.

### Note 14

A light-emitting module, comprising:
the light-emitting device according to any one of notes 1-13;
a substrate including a mounting surface, the substrate comprising:
   a first terminal and a second terminal positioned on the mounting surface; and
a first connection member contacting the first terminal and the first metal film; wherein:
the first metal film comprises a first portion covering the first conductive member, the first portion comprising a first region contacting the first connection member,
the first metal film comprises a second portion covering the second covering part, the second portion comprising a second region contacting the first connection member; and
a first proportion of the first region in the first portion is greater than a second proportion of the second region in the second portion.

### Note 15

The module according to note 14, wherein:
a length of the first connection member in a fourth direction perpendicular to the mounting surface has a maximum at the first portion of the first metal film.

What is claimed is:

1. A light-emitting device, comprising:
a light-emitting element including a first surface, a second surface positioned at a side opposite to the first surface, and a plurality of third surfaces positioned between the first surface and the second surface, the light-emitting element comprising:
a first conductive member and a second conductive member positioned at the second surface and arranged in a first direction;
a covering member comprising:
a first covering part covering a region of the second surface between the first conductive member and the second conductive member, and
a second covering part covering the plurality of third surfaces, wherein:
the covering member does not cover at least a portion of the first conductive member and at least a portion of the second conductive member;
a first metal film covering a portion of the first covering part, the first metal film being electrically connected to the first conductive member; and
a second metal film separated from the first metal film, the second metal film covering a portion of the first covering part, the second metal film being electrically connected to the second conductive member; wherein:
in a second direction from the second surface toward the first surface, a maximum length of the first covering part is greater than a maximum length of the first conductive member, and a maximum length of the first metal film is greater than the maximum length of the first conductive member.

2. The device according to claim 1, wherein:
in the second direction, the maximum length of the first covering part is not less than 2 times and not more than 50 times the maximum length of the first conductive member.

3. The device according to claim 1, wherein:
in the second direction, the maximum length of the first metal film is not less than 0.7 times and not more than 1.2 times the maximum length of the first covering part.

4. The device according to claim 1, wherein:
the first covering part overlaps a portion of the first conductive member and a portion of the second conductive member in the second direction.

5. The device according to claim 1, wherein:
the covering member further comprises a third covering part overlapping the first covering part in the first direction and overlapping the second covering part in the second direction; and
the first metal film covers at least a portion of the third covering part.

6. The device according to claim 5, further comprising:
a light-transmitting member positioned between the second covering part and the third surface of the light-emitting element; wherein:
the third covering part overlaps the light-transmitting member in the second direction.

7. The device according to claim 5, wherein:
a length of the third covering part in the first direction is longer at a side proximate to the light-emitting element in the second direction than at a side distant to the light-emitting element in the second direction.

8. The device according to claim 5, wherein:
a recessed portion defined by the first covering part and the third covering part is open at two ends of the covering member in a third direction that is orthogonal to the first direction and the second direction.

9. The device according to claim 1, wherein:
a portion of the first metal film covering the first conductive member protrudes with respect to a periphery.

10. The device according to claim 1, wherein:
a surface roughness of a portion of the first metal film covering the first conductive member is less than a surface roughness of a portion of the first metal film covering the second covering part.

11. The device according to claim 1, wherein:
the second covering part includes:
a first outer surface overlapping at least a portion of the third surfaces of the light-emitting element in a third direction, the third direction being orthogonal to the first direction and the second direction, and
a second outer surface positioned at a side opposite to the first outer surface; and
the first metal film is positioned to be separated from the first outer surface.

12. The device according to claim 11, wherein:
the second covering part includes:
a third outer surface overlapping the first conductive member in the third direction, and
a connecting surface connecting the first outer surface and the third outer surface;
a length from the first outer surface to the second outer surface in the third direction is greater than a length from the third outer surface to the second outer surface in the third direction; and
at least a portion of the connecting surface is not covered with the first metal film.

13. The device according to claim 1, wherein:
a portion of the second covering part covers a portion of the second surface;
a groove is provided in the portion of the second covering part that covers the portion of the second surface;
the first conductive member includes an exposed portion not covered with the second covering part in the groove; and
the exposed portion is electrically connected to the first metal film.

14. A light-emitting module, comprising:
the light-emitting device according to claim 1;
a substrate including a mounting surface, the substrate comprising:
a first terminal and a second terminal positioned on the mounting surface; and
a first connection member contacting the first terminal and the first metal film; wherein:
the first metal film comprises a first portion covering the first conductive member, the first portion comprising a first region contacting the first connection member;
the first metal film comprises a second portion covering the second covering part, the second portion comprising a second region contacting the first connection member; and
a first proportion of the first region in the first portion is greater than a second proportion of the second region in the second portion.

15. The module according to claim 14, wherein:
a length of the first connection member in a fourth direction perpendicular to the mounting surface has a maximum at the first portion of the first metal film.
